(19) United States
(12) Patent Application Publication
(10) Pub. No.: US 2024/0316494 A1
(43) Pub. Date: Sep. 26, 2024

(54) APPARATUS AND METHOD FOR ELECTRON IRRADIATION SCRUBBING

(71) Applicant: DAPHNE TECHNOLOGY SA, Saint-Sulpice (CH)

(72) Inventors: Juan Mario Michan, Saint-Sulpice (CH); William Jamieson Ramsay, Saint-Sulpice (CH); Dominik Neumayr, Saint-Sulpice (CH)

(73) Assignee: DAPHNE TECHNOLOGY SA, Saint-Sulpice (CH)

(21) Appl. No.: 18/578,877

(22) PCT Filed: Jul. 8, 2022
(86) PCT No.: PCT/EP2022/069018

§ 371 Date: Jan. 12, 2024

(30) Foreign Application Priority Data
Jul. 16, 2021 (GB) 2110271.0

(51) Int. Cl. B01D 53/32; F01N 3/08; H05H 1/24

(52) U.S. Cl. CPC B01D 53/32; F01N 3/0892; H05H 1/2406; B01D 2257/504; B01D 2258/01; B01D 2258/02; B01D 2258/06; B01D 2259/818; H05H 2242/22; H05H 2245/17

(57) ABSTRACT

There is provided a dielectric barrier electrical discharge apparatus and corresponding system and method. The apparatus comprises: at least two electrodes arranged in use to provide at least one anode and at least one cathode, the at least two electrodes being separated to allow a fluid to be present between the electrodes in use, and at least one of the electrodes has a dielectric portion connected to at least part of said electrode; a sub-macroscopic structure connected to at least one of the at least two electrodes and/or to the dielectric portion; and a drive circuit connected to each of the at least two electrodes and arranged in use to establish an electric field between the electrodes, wherein in response to the presence of the electric field between the electrodes, the sub-macroscopic structure is arranged to field-emit electrons and electrical discharge is establishable between the dielectric portion and one of the at least two electrodes, and the drive circuit is further arranged to provide real power to the fluid in use.

### FIELD OF THE INVENTION

The present disclosure relates to methods of capture and/or utilization of components of gas or air by exposure to electrons and electrical discharge and apparatuses therefor. Typically, this is achieved through use of power management, a sub-macroscale structure and a dielectric material.

### BACKGROUND

Global warming caused by greenhouse gas emissions is posing a major challenge to mankind, especially due to the ever-increasing global energy demand. A strong reduction of source greenhouse gas emissions from industry and energy sectors (decarbonisation) is crucial to reaching the ambitious goals of the European Union to become climate-neutral, which is with net-zero greenhouse gas emissions, by 2050.

Unfortunately, as indicated by the International Energy Agency, greenhouse gas emissions from industrial processes can be hard to abate, as they result from chemical or physical reactions, which are vital to the processes themselves. More than half of the models cited in the Intergovernmental Panel on Climate Change's (IPCC) Fifth Assessment Report required carbon capture for a goal of staying within 2 degrees Celsius of warming from pre-industrial days. For models without carbon capture, emissions reduction costs rose 138 percent.

Even as nations diversify their energy portfolios, fossil fuels are expected to meet most of the world's energy demand for several decades. In this context, Carbon Capture, Utilization, and Storage (CCUS) technologies have attracted growing attention due to their potential of significantly reducing greenhouse gas emissions in energy intensive industries.

CCUS is a set of crucial technologies aimed at capturing carbon dioxide (CO2, CO₂) emissions from air and/or point sources (especially industrial sources within the power, chemicals, cement, and steel sectors) to reduce the quantity of CO2 in the atmosphere. CCUS can be divided into two categories, namely Carbon Capture and Storage (CCS) and Carbon Capture and Utilization (CCU) technologies.

CCS processes capture carbon dioxide, which allows its separation from other gases through one of three methods (pre-combustion capture, post-combustion capture and oxyfuel combustion). The captured CO2 is then transported to a suitable site for its final long-term storage (i.e. geological or ocean storage).

However, significant problems have been encountered with CCS technologies, namely the leakage of CO2 from its long-term storage site; several CCS projects have materialized these problems. There is a general difficulty and uncertainty with long term predictions about submarine or underground storage security.

CCU differs from CCS in that CCU does not aim nor result in permanent geological storage of CO2. Instead, CCU aims to convert the captured carbon dioxide into more valuable substances or products, such as plastics, concrete or biofuel, while retaining the carbon neutrality of the production processes.

Hence, the concept of CCU is more appealing than CCS: instead of burying CO2 underground, CO2 can be used as a raw material, in a circular manner, as a replacement for fossil fuels. However, existing technologies to convert captured CO2 is limited by the un-reactivity of CO2; CO2 is a relatively stable molecule with high activation energy.

Although it has been demonstrated that the use of captured CO2 as a feedstock together with “green” hydrogen can produce methanol (biofuel), this route results in an electricity consumption 10 to 25 times higher than that of the CCS routes. This is mostly due to the electricity required to produce hydrogen via electrolysis, with the associated strict requirement of very low carbon-intensity of the electricity mix. Similarly, the use of biomass grown and processed for the specific purpose of making chemicals with captured CO2 requires a land capacity about 40 and 400 times higher than that required by methanol synthesis and CCS routes, respectively, with the associated risks of conflict with other uses.

There therefore remains a technological need for CCU that is (electrically) energy efficient to convert CO2 and with minimal space requirements.

An existing energy efficient technology used for treatment of emissions from fossil fuel burning facilities (such as power stations) is electron beam flue gas treatment (EBFGT). EBFGT allows removal of sulphur oxides (SOx, SOₓ) and nitrogen oxides (NOx, NOₓ) from stack gases (i.e. gases passing through an exhaust stack) at low energy cost by conversion with ammonia (NH3, NH₃) to non-noxious ammonium sulphate-nitrate, usable as an agricultural fertilizer. This technique involves humidified flue gases passing through an electron beam reactor where high-energy electrons bombard nitrogen, water and oxygen to create strong reagents that react with the sulphur oxides and nitrogen oxides to form sulphuric and nitric acids.

In EBFGT, the electron beam reactor is formed by a bank of electron beam accelerators, specifically double-grid tetrode electrode guns in which the cathode housing is located in a vacuum housing. Free electrons are produced in an ultra-clean environment (referred to as ultra-high vacuum) where the pressure is around 12 orders of magnitude lower than atmospheric pressure. The electrons are then accelerated and sent through an aluminium or titanium membrane that separates the ultra-high vacuum environment from the flue stack where the pollutant gases are flowing. The electrons that get through the aluminium membrane collide with the gas molecules and start a chemical chain reaction that removes the pollutants.

However, only a very low proportion of the electrons are emitted from the metal membrane compared to the number incident on the membrane. This makes the process inefficient due to energy being wasted by the energy being converted to heat in the membrane. In addition, implementations of such EBFGT systems require very large capital costs due to the electron accelerator installation. The electron accelerators also require frequent maintenance and extreme safety requirements, which is undesirable or not possible in the location in which the reactor is installed. Further, multiple accelerators must be implemented for redundancy purposes.

The need for an ultra-high vacuum adds expense and can contribute to accelerator failures. Additionally, using this technology for mobile applications is undesirable because the radiation shielding needed to protect against at least X-ray emission and ionization radiation is heavy.

In view of the above circumstances, a practical means for reducing CO2 content and corresponding apparatus capable of favourably converting components (such as CO2) of a gas is therefore still needed.

### SUMMARY OF INVENTION

According to a first aspect, there is provided electrical discharge for use in removing CO2 from a gas. The high-energy electrons generated during the discharge have been found to remove CO2 from gases containing CO2. Since electrical discharge can be provided without the need for a vacuum or an electron beam, and we have found this allows the amount of CO2 in a gas to be reducible, this provides a simplified process by which CO2 is able to be removed from a gas over known techniques. The process reduces the amount of CO2 present in the gas after having been processed.

By the term “discharge”, we intend to mean electrical discharge of some form, such as plasma generating discharge. Typically, this means release and transmission of electricity in an applied electric field through a medium such as a gas. A flow of electrons in the form of a filament passing from one location to another or between two points typically achieves this. The flow of electrons is typically a transient flow of electrons in the form of a filament. By this we intend to mean that the flow of electrons in a microdischarge/filament during electrical discharge lasts for only a short time per individual discharge ignition event. There may of course be many filaments over time if suitable conditions are maintained. The electrical discharge allows transmission of electricity in an applied electric field through gas.

The electrical discharge may be for use in removing CO2 by converting CO2 into one or more other substances. This allows capture and utilisation of the CO2 by the same means, and at the same time, and therefore avoids the need to store CO2.

Any form of electrical discharge may be suitable for removing CO2 from a gas, such as pulse, corona, electron beam, radio frequency, microwave, ultraviolet light radiation electrical discharge, brush, electric glow, electric arc, electrostatic, partial, streamer, vacuum arc, Townsend, field emission of electrons, or electric discharge in gases, leader (or spark), St. Elmo's fire or lightning. Typically however, the electrical discharge may be barrier electrical discharge. We have found that barrier electrical discharge is able to be used to reduce CO2 content in gas, and thereby allowing it to be used to reduce CO2 from air and/or point sources (such as exhaust gases). The presence of the dielectric does not allow arcs or sparks to occur (i.e. discharge that generates sustained current between the electrodes). Instead it only allows microdischarges to occur, which typically only last for microseconds. This provides the necessary energy and components to contribute the chemical reaction pathway by which CO2 is able to be broken down, while limiting the amount of power needed to provide sustained discharge.

Typically, the electrical discharge is dielectric barrier electrical discharge. In using dielectric barrier electrical discharge the discharge is more controllable since less sparking occurs, meaning there is less wear and damage caused by the discharge.

While the gas may be any gas from any source or may simply be gas available locally, such as air, the gas may be a waste gas. Additionally or alternatively the gas may be a gas containing CO2. This allows the electrical discharge to be used to reduce CO2 in air and in exhaust gases, such as flue emissions, from combustion engines, for example in ships and other vehicles, power plants and incinerators.

According to a second aspect, there is provided barrier electrical discharge for use in removing CO2 from a gas.

According to a third aspect, there is provided dielectric barrier electrical discharge for use in removing CO2 from a gas.

According to a fourth aspect, there is provided use of electrical discharge in removing CO2 from a gas.

Typically, the electrical discharge may remove CO2 from a gas, such as by converting the CO2 into one or more other substances.

While any form of electrical discharge can be used, typically the electrical discharge may be barrier electrical discharge. For example, the electrical discharge may be dielectric barrier electrical discharge.

The gas may be air or gas from any local, remote, ambient, environmental or man-made source. Typically the gas may be a waste gas. Additionally or alternatively, the gas may be a gas from an engine.

According to a fifth aspect, there is provided a dielectric barrier electrical discharge apparatus, comprising: at least two electrodes arranged in use to provide at least one anode and at least one cathode, the at least two electrodes being separated to allow a fluid to be present between the electrodes in use, and at least one of the electrodes has a dielectric portion connected to at least part of said electrode; a sub-macroscopic structure connected to at least one of the at least two electrodes and/or to the dielectric portion; and a drive circuit connected to each of the at least two electrodes and arranged in use to establish an electric field between the electrodes, wherein in response to the presence of the electric field between the electrodes, the sub-macroscopic structure is arranged to field-emit electrons and electrical discharge is establishable between the dielectric portion and one of the at least two electrodes, and the drive circuit is further arranged to provide real power to the fluid in use.

Application of a sub-macroscopic structure to the electrodes or dielectric portion is a technically difficult process due to the need to maintain order within the sub-macroscopic structure and the difficulty in attaching the sub-macroscopic structure to the surface of the electrode or dielectric portion. Additionally, using a sub-macroscopic structure implements a “plate to point” sub-macroscopic structure causing a disparity in the homogeneity of the electric field strength since the field strength at an end of the sub-macroscopic structure is higher than on (for example) an electrode that typically has a larger area over which the field is spread. However, we have found that using a sub-macroscopic structure in a dielectric barrier electrical discharge apparatus allows less power to be used than when the sub-macroscopic structure and dielectric portion are not used in combination. This is because, in use, when an electric field is established between an anode and a cathode the sub-macroscopic structure field emits electrons. The field emission causes the gap between anode and cathode to have a raised density of electrons. This saves power as more electrons are present to initiate chemical reactions. This is achieved by combining the classical electrostatic phenomenon of electrical discharge with the quantum phenomenon of tunnelling in the form of field emission when typically, classical and quantum processes are kept separate from each other when used in physical applications. The drive circuit further enhances energy efficiency by maximising real power to the electrodes and dielectric portion (such as in a dielectric barrier discharge, DBD, device).

Accordingly, overall the combination of the drive circuit for an electrode setup implementing a sub-macroscopic structure and dielectric portion arrangement allows sufficient energy efficiency to allow removal of CO2 from a gas to be viable. Further, since this combination converts the CO2 into other substances, the apparatus according to this aspect provides the ability for carbon capture and utilisation providing the environmental benefits set out above for CCU.

By the phrase “real power”, we intend to mean an instantaneous power (p(t)) provided to the electrodes averaged over a period (for example, T0) of an applied voltage, where the period is typically a period from a start of an excitation or start of a power supply window to the start of the next power supply window. Real power (P) can be calculated as:

$$P = \frac{1}{T 0} {\int }_{t 0}^{t 0 + T 0} p ( t ) d t$$

where “t” is time and “t0” is the time at the start of an excitation or start of a power supply window.

As such, real power can also be thought of as meaning a rate of generating high energy electrons in the fluid to be present between the electrodes in use. This provides a conversion of electrical energy (for example, from the drive circuit) to chemical energy (for example, in the fluid between the electrodes during use). This conversion can cause losses due to a number of factors, such as losses in the circuit, electrodes, dielectric and/or to heating the fluid. Such losses are typically unwanted but can be unavoidable in this process. As such, losses may be minimised to have a maximal rate of production of high energy electrons.

By the sub-macroscopic structure being connected to at least one of the electrodes or dielectric portion, we intend to mean that at least one sub-macroscopic structure is connected to at least one electrode or dielectric. This means that more than one electrode and/or the dielectric portion may have one or more sub-macroscopic structures connected thereto. There may of course be a plurality of sub-macroscopic structures, each sub-macroscopic structure being connected to one of an electrode or the dielectric portion, such as all the sub-macroscopic structures being connected to only a single electrode or only the dielectric portion, or one or more electrodes and/or the dielectric portion having one or more sub-macroscopic structures connected thereto. It is intended that when a sub-macroscopic structure is connected to an electrode or the dielectric portion, that sub-macroscopic structure is only connected to that respective electrode or the dielectric portion, and not also connected to an or another electrode or the dielectric portion (when connected to an electrode).

The fluid is typically a gas, but may be another type of fluid, such as a liquid.

The real power provided by the drive circuit may be a (predetermined) amount of real power such that the drive circuit may be arranged to provide an amount of real power to the fluid. This may be a fixed amount of real power, but this is typically not useful due to fluctuations and variations in the amount of instantaneous and/or real power transferred to the fluid, and thereby drawn from the drive circuit. This can be due to slight changes in conditions of the fluid, such as the content, temperature and/or flow rate of the fluid. Accordingly, typically the amount of real power is an adjustable (by which we intend to mean variable or modifiable) amount of real power such that the drive circuit may be arranged to provide an adjustable amount of real power to the fluid.

The sub-macroscopic structure can be any sub-macroscopic structure, such as a mesoscopic structure. Typically, the sub-macroscopic structure may be a microstructure or smaller. For example, the sub-macroscopic structure could be a carbon, silicon, titanium oxide or manganese oxide nanowire, nanotube or nanohorn, or stainless steel, aluminium or titanium microneedles.

The sub-macroscopic structure may be a carbon nanotube (CNT) or a microneedle. CNTs and microneedles have been found to be very good field-emitters of electrons when exposed to an electric field. This is because these sub-macroscopic structures can produce large numbers of electrons at relatively low applied voltages because of their very high aspect ratio (typically 50 to 200 nanometres, nm, diameter versus 1 to 2 millimetres, mm, in length, i.e. 5,000 to 40,000 aspect ratio) and their low work function (typically around 4 electron volts, eV). The high aspect ratio causes a large field enhancement at the tips of the sub-macroscopic structures with several volts per micrometre, also referred to as a micron, (V/μm) achievable at low applied voltages. The minimum electric field strength required for field-emission from such a sub-macroscopic structure is generally around 30 V/μm. This can be achieved by varying one or more of the length of the sub-macroscopic structure, the diameter of the sub-macroscopic structure, the distance between the electrodes used to create the electric field, and the applied voltage used to establish the electric field. If an array of (individual) sub-macroscopic structures is used, the density of the array can also be varied to vary the electric field strength since sub-macroscopic structures tend to shield one another.

The sub-macroscopic structure could be a multi-walled CNT (MWNT) or a metallic single walled CNT (metallic SWNT).

The drive circuit may be arranged in use to provide real power to the fluid by applying a pulse-train of bipolar voltage pulses with a limited number of pulses in the pulse-train. This allows the DBD device to be excited with a high voltage slew rate while substantially reducing current stress, and which lowers the peak power processed by the power electronics.

Further, the drive circuit may be arranged in use to provide real power to the fluid by applying a pulse-train of bipolar voltage pulses with between one and five pulses in the pulse-train. Repetition frequency of pulses may be limited by a maximum operating temperature of power electronics. In general, pulse-power converter designs take advantage of the slow thermal response. This means that if a high pulse repetition frequency were used in a conventional pulsed system, dissipated peak power would be too large to stay within safer operating temperatures of the power electronics. This is reduced by limiting the maximum number of discharge ignition events produced from a single pulse-train and then having a period that allows cooling to occur before the next pulse-train. By implementing a pulse-train of several consecutive bipolar voltage pulses, with the number of discharge ignition events is limited to between one and five, by limiting the number of pulses in the pulse-train to a corresponding or similar number, this is achieved while providing energy transfer at very high efficiency, such as at about 90% efficiency or greater.

The real power provided by the drive circuit may be provided by the drive circuit being arranged in use to maintain the electric field strength above a threshold. This threshold may be a threshold at which discharge ignition is able to occur. By providing such discharge this is able to cause transfer of real power to the fluid by generation of high energy electrons that interact with the fluid, enabling breakdown of fluid or components of the fluid.

The drive circuit may provide real power through any suitable means, such as by providing a constant supply of power at a set amount, from a DC power supply of some form, or by providing a constant AC power supply or continuous supply of power in a sinusoidal waveform at a predetermined frequency. Typically, the drive circuit may further comprise a power supply connected in use across the at least two electrodes, and an inductance connected between the power supply and at least one of the at least two electrodes thereby establishing a resonant tank in use, power being provided in use to the tank in pulse-trains and only during a pulse-train, a pulse frequency of each pulse-train being tuneable in use to a resonant frequency of the tank, power provided by each pulse-train charging and maintaining the tank to a threshold at which discharge ignition occurs, discharge ignition events per pulse-train being limited to a maximum number based on the drive circuit being arranged in use to prohibit each pulse-train transferring power to the resonant tank after the maximum number has occurred.

By providing pulse-trains of power to the resonant tank, the amount of energy stored in the resonant tank increases, also referred to as “charging” the resonant tank, over the duration of each pulse-train. Dielectric barrier electrical discharge occurs across the dielectric discharge gap when the potential difference across the gap reaches a threshold (Vₜₕ). By tuning the pulse frequency (by which we intend to mean the reciprocal of the period between individual pulses or cycle period of pulses within a pulse-train) of the pulse-trains to a resonant frequency of the tank the charging process causes a rapid increase in the amplitude of the potential difference. This increases the potential difference amplitude to the threshold over, for example, less than ten cycles, to reach a threshold at which dielectric barrier electrical discharge occurs (which can also be referred to as an “ignition threshold”).

A limitation on current imposed stress is provided by using the device of an aspect described herein. Limitation on current imposed stress is achieved using such a device by the build up to the potential difference to the threshold occurring over several cycles (i.e. individual pulses) during the pulse-train by means of the resonant tank voltage gain resulting in reduced power losses in the driving circuit. In conventional multi-pulse systems, plasma discharge is provided by use of a single pulse, requiring a high step-up transformer, resulting in a higher current, and thereby raising current imposed stress, for example, on the primary winding side.

Further, the power supply is protected from short-circuits without needing overcurrent detection. This is due to the inductance of the resonant tank providing enough impedance to limit currents if the output terminal of the power supply is shorted, for example, due to a short circuit failure at the dielectric barrier.

Additionally, by limiting the number of discharge ignition events, there is a reduction in dissipation of energy simply to heat or generation of less reactive species. Indeed, we have found that by implementing such a hybrid of resonant AC and limited pulse excitation effective pollutant reduction is providable while also having high power conversion efficiency.

Accordingly, overall, in a device according to an aspect, power transfer to the dielectric barrier discharge device with a high efficiency is achieved (due to the resonance effect) while also limiting current imposed stress and protecting against short-circuits so as to protect circuit components.

There is typically a temporal difference between the end time of one pulse-train and the start of the next pulse-train. In other word, there may typically be a period of time between the end of one pulse-train and the start of the next pulse-train during which there are no pulses, which allows one pulse-train to be distinguished from the next pulse-train and avoids any concurrent portions or overlap between consecutive pulse-trains.

The dielectric discharge gap is intended to be a gap between electrodes of a dielectric discharge device. This typically provides a capacitance due to the gap, with a further capacitance being provided by the dielectric. Of course, when the drive circuit according to the aspect is connected across the discharge gap, since the edges/sides of this gap are provided by the electrodes, it is intended the drive circuit is connected (i.e. electrically connected) to at least the electrodes in a manner that allows the drive circuit to provide current to the electrodes and establish a potential difference across the electrodes. In various examples, the drive circuit may still be connected across the dielectric discharge gap by being connected to wires or cabling connected to the electrodes that form a closed circuit that includes the drive circuit and dielectric discharge gap.

The cycle period of power being supplied by the resonant tank is intended to refer to the period taken for the current and/or voltage to pass through a single oscillation cycle (only) as determined by the frequency. In other words, this is intended to be the time taken for the current and/or voltage to pass through a single wavelength (only).

The presence of the dielectric at the dielectric discharge gap typically does not allow arcs or sparks to occur (i.e. discharge that generates sustained current between the electrodes). Instead, it typically only allows microdischarges to occur, which typically only last for microseconds. This provides the necessary energy and components to contribute to a chemical reaction pathway to break down compounds in the medium through which the discharge is passing, while limiting the amount of power needed to provide sustained discharge.

A process by which discharge caused by a drive circuit according to an aspect described herein can be thought of as there initially being an absence of discharge occurring before an ignition threshold is reached. This means gas in the discharge gap (such as between electrodes) has not been ionized, and there is no electric discharge, and, of particular relevance, power is not delivered to the gas. Once the threshold is reached discharge occurs however. This results, from a single point (such as some form of sub-macroscopic structure on the surface of an electrode defining a side of the discharge gap), in innumerable transient filaments (each representing a micro-discharge) being formed. Each filament's lifetime (i.e. the period of time during which a respective filament exists) is of the order of tens of nanoseconds. It is only during the lifetime of these transient micro-discharges that high energy electrons are formed in the discharge gap, allowing power to be delivered to the medium in the gap. The power delivered by high energy electrons that are generated is able to initiate pollutant breakdown due to the energy levels being of a sufficient amount to initiate chemical reactions.

Maintaining a discharge gap at the voltage threshold indefinitely causes charge accumulation on the surface of the electrodes and dielectric barrier of a dielectric discharge gap of a DBD device. This can be avoided by the use of pulses. Pulses can be thought of, due to the alternating polarity provided by pulses, as limiting the amount of time the instantaneous voltage at the discharge gap is maintained at the ignition threshold to a period in the order of a few microseconds. This means that transient filaments are only able to be produced for this period. As such, the period in which microdischarges can occur can be thought of as limited to the amount of time the instantaneous voltage at the discharge gap is maintained at the ignition threshold, and the summation of those transient filaments may be considered to be a “macro-discharge” or “discharge event”.

In view of the preceding four paragraphs, the term “discharge ignition event” is therefore intended to be the start of a macro-discharge or discharge event, or, in other words, the start of the period during which micro-discharges in the form of transient filaments are able to occur, which is when a threshold is reached. This threshold is typically a voltage threshold, such as a voltage threshold at the dielectric discharge gap, for example in the form of a potential difference (e.g. ΔV) across the electrodes/dielectric layer and electrode delimiting the gap.

The pulse frequency of the pulse-train being tuneable in use to a resonant frequency (also able to be referred to as a “resonance frequency”) of the tank, is intended to mean that the pulse frequency may be tuned to one or more of a number of frequencies that is able to be considered the resonant frequency.

These include the theoretical resonant frequency (i.e. the frequency that would be calculated as being the resonant frequency when not accounting for real-world effects), or a practically applicable resonant frequency, such as a frequency that takes account of real-world effects, which may include one or more of inductance and/or resistance in wiring and/or other components, damping or impedance. As such, as detailed further below, a zero voltage switching frequency.

The maximum number of discharge ignition events may typically be between one and five events, such as between one and three events, including (only) one event, two events or three events. By limiting to so few discharge ignition events, we have found this produces the most energy efficient and effective breakdown of pollutants. This is due to the energy transfer that occurs due to the discharge ignition event(s) limiting transfer to the medium in the discharge gap, and thereby directing a higher proportion of the energy to cause breakdown of compounds in the medium.

The drive circuit may further comprise a phase meter in communication with the tank and arranged in use to identify (such as by monitoring) a phase shift in power provided to the tank during each pulse-train, the phase shift corresponding to occurrence of discharge ignition events, and wherein the drive circuit may be further arranged in use to determine when the maximum number of discharge ignition events has occurred based on the number of pulses in the respective pulse-train since each respective discharge ignition event.

We have found that such a phase shift represents the start of discharge, and, as such, it is possible to identify the number of discharge ignition events that occur from that point (such as by counting or being aware of the number of pulses in the pulse train from that point onwards). This means it is possible to determine when a maximum number of discharge ignition events has been reached to stop further discharge ignition events occurring. By monitoring a voltage-current phase-shift at, for example, an input to the resonant tank (such as a voltage-current phase-shift measured at the H-bridge terminal, relevance of which H-bridge being detailed further below) a first discharge ignition event may be detected. During charging of the resonant tank (e.g. the rapid voltage built-up) there is typically close to zero phase-shift (excited at resonance). However, once the plasma is ignited as part of the discharge ignition event, there is typically a shift in the resonance frequency because of the increase in capacitance imposed by the “ignited” discharge gap. When monitored, this resonance frequency shift may be detected immediately by monitoring the phase-shift.

Such a phase meter (e.g. a phase detection unit) as mentioned above may be provided by a controller, processor, microprocessor or microcontroller or another such device capable of monitoring phase of at least two signals.

Additionally or alternatively to phase monitoring or using a phase meter, each pulse-train may have a pre-tuned or optimised pulse-number (i.e. number of pulses within the pulse-train). It is typically possible to calculate or model how many pulses will be needed to charge the resonant tank, and typically there is (only) a single discharge ignition event per pulse, or at least it is possible to calculate how many discharge ignition events will be caused per pulse. This allows it to be possible to set the number of pulses in a pulse-train to at least the maximum number of discharge ignition events wanted plus the number pulses needed to charge the tank. If such an approach is used, there may of course be further pulses included in a respective pulse-train, such as when pulses are used to discharge the resonant tank. These may also be included in calculation of how many pulses are needed per pulse-train if this approach is used.

In other words, this phase difference can also be used to detect the beginning of the occurrence of dielectric barrier discharges. Detecting this can allow it to be identified when transition the pulse-train from providing energy to, for example, energy recovery after a defined number of discharge ignition events. As also mentioned above, the occurrence of dielectric barrier discharge in the discharge gap increases the effective capacitance. This results in a reduction of the resonance frequency, and hence an increase of the measurable phase difference for a given driving frequency (such as the pulse frequency of the pulse-trains). In view of this, it can be seen that the phase meter of the drive circuit and the controller may be the same component as each other. Alternatively the controller and phase meter may be in communication with each other, or the controller may incorporate the phase meter, such as the phase meter being a component of the controller.

The drive circuit may further comprise a transformer, secondary windings of which form part of the resonant tank, the transformer being a step-up transformer. This lowers the minimum voltage gain needed in the resonant tank to achieve dielectric barrier electrical discharge voltage levels (i.e. Vₜₕ) by raising the voltage input level. Additionally, the use of a transformer reduces ground currents (currents flowing in the parasitic capacitance between electrodes of the DBD device and any surrounding metallic housing), thereby reducing EMI. While a transformer could be located within the circuit with the primary windings forming part of the resonant tank instead of the secondary windings, in the arrangement where the secondary windings form part of the resonant tank, the kilo-Volt-Ampere (kVA) rating of the transformer is able to be reduced. In such a case, a reactive power of the DBD device may be compensated.

The drive circuit may be arranged in use to short the primary transformer winding after each pulse. This reduces ringing that may occur due to the components that make up the resonant tank. When an inverter is used, the shorting of the transformer primary windings may be achieved in use by switching on a low side or high side of the inverter. This avoids the need to include further components in the circuit, thereby limiting component count.

The inductance of the resonant tank may be provided or contributed to by one or more components, and may be provided by inductance in wiring or cabling between components within the circuit. At least a part of the inductance (such as some or all of the inductance) may be provided by the transformer. This uses a typically undesirable property of a transformer allowing that property to be used as a contribution to the functioning of the circuit. Any inductance provided by the transformer may be leakage inductance (also referred to as stray inductance) of the transformer. In some circumstances this can allow the resonant tank to not need to also include an inductor as a specific component.

Additionally or alternatively, to a transformer providing inductance, at least a part of the inductance (such as some or all of the inductance) may be provided by an inductor. This provides a component designed to provide inductance to be used, thereby optimising the circuit. In a situation where the inductance is provided partially or wholly by an inductor and a transformer, each contribute to inductance between the power source and the dielectric discharge gap, and thereby to inductance of the resonant tank.

The drive circuit may further comprise a power storage device connected across the power supply arranged in use to accept and store power discharge (i.e. power drained) from the tank after each pulse-train. This provides a means for storing/recouping power within the circuit that would otherwise be lost due to energy in the resonant tank dissipating. This reduces energy loss between pulse-trains and allows the stored energy to contribute in forming the next high voltage pulse-train. This saves energy and therefore makes the circuit more efficient.

Energy or power recuperation is able to be achieved through passive or active means. Typically, an active means is used, such as the drive circuit typically being arranged in use to shift the phase of (pulses in) the pulse-train by 180 degrees (°) after the maximum number of discharge ignition events has occurred. By implementing this mechanism, energy recovery is able to be achieved when passive means for energy recovery (and potentially any other active means) are not possible, such as due to use of a loosely coupled air-core transformer. This thereby allows the efficiency gains achievable from energy recovery to still be achieved. The phase shift may be in place for the same number of pulses as the number of pulses used in the pulse-train to charge the resonant tank to the threshold, although it would be possible to apply the phase shift for a different number of pulses. This maintains similar power flows when charging and discharging the resonant tank.

The sub-macroscopic structure may be electrically connected to at least one of the electrodes. Additionally or alternatively, the or each electrode to which the or each sub-macroscopic structure is electrically connected may be arranged in use to provide a cathode.

According to a sixth aspect, there is provided an apparatus for (i.e. suitable for) removing carbon dioxide from a gas, the apparatus comprising: a first electrode and a second electrode, the first and second electrodes being arranged in use to provide an anode and a cathode; a dielectric portion connected to the first electrode and a sub-macroscopic structure connected to the first or second electrode or to the dielectric portion, wherein, in response to the presence of an electric field between the electrodes, the sub-macroscopic structure is arranged to field-emit electrons and electrical discharge is establishable between the dielectric and the second electrode; a drive circuit connected to the first electrode and the second electrode and arranged in use to establish an electric field between the first and second electrodes, wherein in response to the presence of the electric field between the electrodes, the sub-macroscopic structure is arranged to field-emit electrons and electrical discharge is establishable between the dielectric portion and one of the at least two electrodes, and the drive circuit is further arranged to provide real power to a fluid (such as the gas) to be present between the electrodes in use; and a housing coupled to the electrodes, the electrodes being located on the housing so that the sub-macroscopic structure and the dielectric portion each extend into a container containing gas to be scrubbed such that an interior of said container can be exposed to said electrons and electrical discharge.

The use of the dielectric portion, the sub-macroscopic structure and drive circuit provide a synergistic effect of lowering the power and voltage needed to establish electrical discharge while allowing CO2 to be removed from gas. Additionally, using the dielectric portion allows the discharge to be more controllable by reducing the amount of sparking and thereby the amount of wear and damage caused by electrical discharge. If the sub-macroscopic structure was used without the dielectric portion, the larger amount of sparking would limit the usefulness of the sub-macroscopic structure since this is typically more susceptible to damage form sparking than other parts of the apparatus. Conversely, if the dielectric were used without the sub-macroscopic structure, the density of electrons to initiate CO2 breakdown would be lower and thus require higher energies to achieve the same reduction efficiency. Additionally, the use of the drive circuit reduces power wastage, and therefore increases the overall efficiency. As such, the combined effect of using the dielectric, the sub-macroscopic structure and drive circuit has a greater benefit than the benefits offered of using each independently.

The real power provided in this aspect may be provided in the same manner as set out above in relation to the earlier aspect. For example, the drive circuit may be arranged in use to provide real power to the fluid by applying a pulse-train of bipolar voltage pulses with a limited number of pulses in the pulse-train. Further, the drive circuit may be arranged in use to provide real power to the fluid by applying a pulse-train of bipolar voltage pulses with between one and five pulses in the pulse-train.

It is intended that the housing may be arranged to allow removal of CO2 from a gas within the housing. This may be achieved by the electrodes being located on the housing so that the sub-macroscopic structure and the dielectric portion each extend into the container.

The first electrode may be arranged in use to provide the anode (or an anode if there is more than one anode, such as when there are more than two electrodes). Additionally or alternatively, the second electrode may be arranged in use to provide the cathode (or a cathode if there is more than one cathode, such as when there are more than two electrodes).

The sub-macroscopic structure may be electrically connected to one of the electrodes. Typically, the sub-macroscopic structure is electrically connected to the second electrode.

The electrodes may be any suitable material for providing electrodes that allow an electrical field to be established therebetween. Typically, the electrodes may be made of an electrically conductive metal.

The dielectric portion being connected to the first electrode and the sub-macroscopic structure being connected to the second electrode allows application of the dielectric portion and sub-macroscopic structure to the respective electrodes to be independent. This avoids the possibility of the processes for applying the dielectric portion to the electrode and for applying the sub-macroscopic structure to the electrode damaging the sub-macroscopic structure or dielectric respectively. Accordingly, this simplifies the process of manufacturing the apparatus and reduces the failure rate in manufacture.

The following features may be applicable to any aspect.

The dielectric portion may provide a form of covering of at least part of the or each electrode to which it is connected. Typically, the dielectric portion is a coating on at least part of a surface of the or each electrode to which the dielectric portion is connected. For example, the dielectric portion may coat the entire surface of the or each electrode to which it is connected.

The dielectric portion may have a thickness of between about 0.1 mm and 10 mm, such as about 2 mm.

By the dielectric portion being connected to at least one electrode, we intend to mean that each electrode to which the dielectric portion is connected is connected to a dielectric portion independently of each other dielectric portion and electrode. This means there may be a plurality of dielectric portions. Each dielectric portion may be connected to only a single electrode.

The dielectric portion may be one or more of mica, quartz, fused silica, alumina, titania, barium titanate, fused silica, titania silicate, silicon nitride, hafnium oxide or a ceramic. By the phrase “one or more of” in this case we intend to mean a combination of two or more of the named materials when two or more of these are used.

Typically, the dielectric portion is quartz. This is because quartz as this material is readily available, low cost, can be processed in large quantities and can have a high resistance to thermal stress. The dielectric portion may alternatively be mica. Mica is beneficial because it has a slightly higher dielectric constant than other dielectric materials, such as glass.

As set out above, the sub-macroscopic structure may be any form of suitably sized sub-macroscopic structure. Typically, the sub-macroscopic structure may be a nanostructure.

The nanostructure may have an aspect ratio of length to width of at least 1,000 (i.e. 1,000 to 1). A nanostructure with an aspect ratio of at least 1,000 provides more efficient field emission than those with a lower aspect ratio. The aspect ratio may be at least 5,000 or at least 10,000. Increasing the aspect ratio has been found to further increase the efficiency of the field emission.

As an alternative to a nanostructure, the sub-macroscopic structure may be a microstructure. Typically, the microstructure may have an aspect ratio of length to width of at least 5 (i.e. 5 to 1), such as an aspect ratio or at least 8, 9 or 10. Microstructures typically do not field-emit as efficiently as nanostructures, such as CNTs. However, using microstructures, such as microwires, simplifies manufacture of the apparatus since large arrays of vertically aligned microstructures can be easily manufactured on an industrial scale.

The apparatus may further comprise a substrate on which each sub-macroscopic structure is formed or is located. The substrate may be electrically conductive.

The substrate may be comprised in or electrically connected to the cathode.

The substrate may comprise one or both of silicon and a metal. The silicon may be highly doped conductive silicon. The silicon may be coated with aluminium at least on a side on which said sub-macroscopic structure is formed or located. The metal may comprise titanium, and/or a titanium alloy, and/or aluminium, and/or an aluminium alloy and/or copper, and/or a copper alloy. The metal may be polished.

The sub-macroscopic structure may be coated with one or more low work function materials, such as up to 4 eV. This improves the field emission of the sub-macroscopic structure. Alternatively, or additionally, the sub-macroscopic structure may be doped with electron transport enhancing or electrical conductivity enhancing materials. This makes the field emission more efficient. For example, Group III (acceptor) or Group V (donor) atoms (e.g. phosphorous or boron) could be used in silicon nanostructures.

The sub-macroscopic structure may be at least partially coated in a material having a work function of up to or less than 4 eV. Said material may be caesium or hafnium.

The coating material may have a melting point of at least 400° C.

The sub-macroscopic structure may be at least partially coated in a catalytic coating. Said catalytic coating may be one or more of cobalt, rhodium, iridium, nickel, palladium, platinum, silver, gold, vanadium oxide, zinc oxide, titanium dioxide and tungsten trioxide. Said catalytic may be applied over a stabilizing coating, such as titanium dioxide.

The sub-macroscopic structure may be an array of (individual) sub-macroscopic structures. The array may comprise a combination of at least two of: one or more uncoated sub-macroscopic structures, one or more sub-macroscopic structures at least partially coated in a material having a work function of less than 4 eV, and one or more sub-macroscopic structures at least partially coated in a catalytic coating.

The sub-macroscopic structure may be hollow. When the sub-macroscopic structure is hollow, the interior of the sub-macroscopic structure may be at least partially filled with a stiffening material. The stiffening material may include a transition metal such as titanium, iron or copper. The stiffening material may include a material of the substrate on which the sub-macroscopic structure may be formed. The substrate may comprise titanium. The stiffening material may comprise titanium carbide.

The sub-macroscopic structure may be doped with an electron transport enhancing or electrical conductivity enhancing material.

In some examples the electrodes are arranged in use to be between 20° C. and 500° C. In other examples, the electrodes are arranged in use to be between 100° C. and 400° C., such as at 150° C. These temperatures allow the apparatus to operate optimally. A temperature of 150° C. is typically considered as the temperature at which the chemical pathway for breaking down CO2 is optimised while minimising material breakdown of the components of the apparatus at the same time.

If titanium dioxide is used, either to form the sub-macroscopic structures or to coat the sub-macroscopic structure, the temperature of the sub-macroscopic structures (for whatever reasons, such as due to deliberate heating for self-repair or as a result of exposure to hot exhaust gas) should be kept below 600° C. This is because above this temperature, titanium dioxide changes from an anatase structure to a rutile structure, which is undesirable.

The drive circuit may be arranged in use to provide a voltage pulse to said at least one electrode. The voltage pulse increases the ionisation of gas between the electrodes thereby speeding up the process of removing CO2 from the gas.

The drive circuit may be arranged in use to provide a voltage pulse having at least one of the following: a duration between 1 nanosecond (ns) and 1 millisecond (ms); and a repeat periodicity of between 100 Hertz (Hz) and 10 MHz, the pulse repetition preferably forming a pulse train with a duty cycle of less than 50%.

The drive circuit may further comprise an inverter between the power supply and the tank, the inverter being arranged in use to modulate supply of power to the tank from the power supply. This allows the characteristics and properties of the power provided to the resonant tank to be determined by components within the drive circuit instead of by any input to the drive circuit. This provides a great amount of customisation and alterations to be made than when this is determined by power provided at a drive circuit input.

The inverter may be any suitable type of inverter. Typically, the inverter is an H-bridge or half bridge. This provides a simple mechanism for providing the inverter functionality while also allowing direct and easy control over the output from the inverter to achieve passive and/or active recuperation of the energy stored in the tank at the end of every pulse-train.

When an H-bridge or half bridge is used, the switches used in the bridge inverter may be any suitable switch, such as a mechanical switch or power transistor switches. Typically each switch of the inverter may be a silicon or silicon carbide (Metal Oxide Semiconductor Field Effect Transistor, MOSFET) switch, a silicon insulated-gate bipolar transistor (IGBT) switch, or a gallium nitride power transistor (FET) switch. A silicon MOSFET switch typically has a blocking voltage of about 650 V; a silicon carbide (SiC) MOSFET switch typically has a blocking voltage of about 1.2 kV; a silicon IGBT switch typically has a blocking voltage of about 650 V or about 1.2 kV; and a gallium nitride FET switch typically has a blocking voltage of about 650 V. It is also possible to use a multi-level bridge-leg with several low-voltage devices connected in series to achieve a high(er) blocking voltage bridge-leg. However, typically a mechanism is needed to make sure that the voltage is shared equally across the switches, which makes things complicated and less rugged. This is why the 2-level H-bridge is typically used in the drive circuit according to an aspect. The use of the above switches in the inverter also allows the components to be kept simple. Wide bandgap (WBG) semiconductors, such as SiC and GaN, are typically used due to their superior performance over Si based power semiconductors.

The pulse frequency (such as of the frequency of a voltage waveform if provided as a pulse-train) supplied to the resonant tank may be exactly the resonance frequency of the tank, such as the frequency of the first order harmonic (i.e. fundamental frequency or natural frequency), or at around the resonance frequency, such as within a range of the resonance frequency. If a higher order harmonic is used, due to the resonant tank typically having low pass characteristics, higher order harmonics than the first order harmonic are attenuated or damped. This is why the resulting current and voltage across the dielectric discharge gap is almost perfectly sinusoidal even though the excitation is typically provided in a square waveform.

When an inverter using switches, such as an H-bridge or half bridge inverter is used, the pulse frequency of each pulse-train may be a zero voltage switching (ZVS) frequency. This is typically slightly above the exact resonance frequency of the tank, such as about 5% to about 10% above the exact resonance frequency, and no more than about 10% depending on the Quality (Q) factor of the drive circuit. This reduces losses caused by the switching and reduces electromagnetic interference (EMI) caused by the switching, thereby making the inverter more efficient and reducing noise produced by the inverter.

The drive circuit may further comprise a transformer, secondary windings of which form part of the resonant tank, the transformer being a step-up transformer. This lowers the minimum voltage gain needed in the resonant tank to achieve dielectric barrier electrical discharge voltage levels (i.e. Vₜₕ) by raising the voltage input level. Additionally, the use of a transformer reduces ground currents (currents flowing in the parasitic capacitance between the electrodes and any surrounding metallic housing), thereby reducing EMI. While a transformer could be located within the drive circuit with the primary windings forming part of the resonant tank instead of the secondary windings, in the arrangement where the secondary windings form part of the resonant tank, the kilo-Volt-Ampere (kVA) rating of the transformer is able to be reduced. In such a case, a reactive power of the dielectric barrier (DBD) device defined by the electrodes and dielectric portion may be compensated.

When a transformer is used, the drive circuit may be arranged in use to short the primary transformer windings after each pulse-train. When energy is being recovered/recuperated from the tank, the shorting of the primary windings is typically applied after the energy has been recovered, such as after a respective pulse-train has elapsed. Shorting the primary windings reduces ringing that may occur due to the components that make up the resonant tank. When an inverter is used, the shorting of the transformer primary windings may be achieved in use by switching on a low side or high side of the inverter. This avoids the need to include further components in the drive circuit, thereby limiting component count.

The inductance of the resonant tank may be provided or contributed to by one or more components, and may be provided by inductance in wiring or cabling between components within the drive circuit. At least a part of the inductance (such as some or all of the inductance) may be provided by the transformer. This uses a typically undesirable property of a transformer allowing that property to be used as a contribution to the functioning of the drive circuit. Any inductance provided by the transformer may be leakage inductance (also referred to as stray inductance) of the transformer. In some circumstances this can allow the resonant tank to not need to also include an inductor as a specific component.

As set out in more detail below, the transformer may be an air-core transformer. When an air-core transformer is used, this may have up to 60% magnetic coupling between windings. The use of an air-core transformer, such as an air core-transformer with 60% magnetic coupling between windings, enhances the inductance able to be provided by the transformer, reducing the need for the resonant tank to have any further inductance. Additionally, the resonance inductance, and thereby the resonant frequency of the resonant tank, may be tuned by adjusting the distance between the primary windings (also referred to as the transmitting coil) and the secondary windings (also referred to as the receiving coil) when using an air-core transformer. This reduces the need for placement of additional capacitors, as is known to be carried out in existing systems, into the circuit, thereby reducing component count. This is achievable due to planar inductive power transfer that occurs when using air-core transformer. Other arrangements that allow an air-core transformer to be implemented are also possible.

Air-core transformer windings have low coupling compared to other transformers (i.e. non-air core or solid core transformers). This allows the secondary (i.e. high voltage) side of the transformer to oscillate freely when no voltage is impressed from the primary side (such as when all switches are off and body diodes not conducting). The means for active energy recovery detailed above (i.e. the 180° phase shift of some pulses) removes these oscillations and avoids power losses when an air-core transformer is used.

The transformer may have a step up ratio of primary transformer windings to secondary transformer winding of about 1:1 to about 1:10, such as about 1:5. By applying this arrangement, the following equation holds, which it typically does not for known systems:

$$\frac{{V}_{d c}}{n} < \frac{{V}_{t h}}{2}$$

where V_{dc} is the voltage provided by a DC link power source, n is the turns ratio of the transformer (i.e. N₁/N₂, corresponding to the number of primary windings divided by the number of secondary windings), and Vₜₕ is the ignition voltage or discharge threshold of the DBD device. As set out in the next paragraph, this reduces the gain needs.

For a dielectric barrier electrical discharge ignition voltage threshold in a DBD device of about 20 kV, this means that a minimum resonant tank voltage gain of about a factor 5 is needed for a step up ratio of about 1:5 when the input voltage to the drive circuit is about 800 V. This achieves an optimised balance between transformer step-up and resonant tank voltage gain, significantly reducing the currents stress of the drive circuit, compared to a conventional pulsed-power and resonant converter system relying primarily on a high step-up transformer (1:20 or greater) to attain the required discharge voltage levels.

Until the discharge threshold is reached, there is minimal damping in the resonant tank. This is because there is no load (such as power transfer to the medium in the discharge gap) on the resonant tank during charging. As a comparison to known resonant systems, in such systems, there is typically always a load because there is continuous or prolonged discharge, which generates a load.

The lack of load on the resonant tank of a drive circuit according to an aspect described herein results in very high voltage gains (such as gains with Q values of greater than 50) compared to known systems. Unlike known systems, the achievable voltage gain of the resonant tank, does not depend on the load (as noted, typically corresponding to the power transferred to the gas when dielectric discharge occurs). Instead, it (only) depends on the parasitic resistances of the resonant tank (such as those produced by resistance of the magnetics and electrodes).

Further, due to there being a lack of load, this allows more rapid charging and for the pulse frequency of the pulse-trains to be as close as possible to the true resonance frequency of the tank (such as the theoretical resonance frequency that does not account for damping effects typically present in reality). This is because the amount of damping is so low that minimal account needs to be taken of damping when the pulse frequency is set. This enhances the energy transfer ability, making the drive circuit more efficient.

When there is a transformer, the dimensioning needed of the transformer step-up turns ratio (i.e. the specification set for the transformer step-up turns ratio) also only depends on the parasitic resistances of the resonant tank. Should there be a load to account for as well, dimensioning of the transformer step-up turns ratio would also need to account for this. This allows losses from the transformer to be kept to a minimum thereby reducing the effect of using a transformer on the efficiency of the drive circuit compared to when a load does need to be considered.

Alternatively or additionally to a transformer providing inductance, at least a part of the inductance (such as some or all of the inductance) may be provided by an inductor. This provides a component designed to provide inductance to be used, thereby optimising the drive circuit. In a situation where the inductance is provided partially or wholly by an inductor and a transformer, each contribute to inductance between the power source and the dielectric discharge gap, and thereby to inductance of the resonant tank.

When a separate transformer and inductor are provided, there are several possible arrangements of the drive circuit. One arrangement is for the inductor to be connected to the input to the resonant tank (such as the output of the inverter), this is in turn connected to the primary winding of the transformer; the secondary windings of the transformer are then connected across the dielectric discharge gap. A further arrangement is for the input to the resonant tank to be connected to the primary winding of the transformer; the secondary winding is connected to the inductor, which is connected in series with the dielectric discharge gap. In each of these arrangements, the leakage or stray inductance of the transformer contributes to a resonance inductance value (i.e. the inductance) of the resonant tank. Naturally, if the resonant tank is placed after the transformer, the kVA rating of the transformer is reduced because the oscillating reactive power of the dielectric discharge device is not passing through the transformer.

Another arrangement is for the input to the resonant tank to be connected to the primary winding of the transformer; and the secondary windings of the transformer are connected across the dielectric discharge gap. In this arrangement, since no separate inductor component is provided, the leakage or stray inductance of the transformer would need to be large enough to compensate the load across the dielectric discharge gap at a desired resonance frequency. This can be achieved by means of a transformer with very low coupling between windings as it is the case for an air core transformer (i.e. without magnetic core) as referred to in more detail below.

The drive circuit may further comprise a power storage device connected across the power supply arranged in use to accept and store power discharge (i.e. power drained) from the tank after each pulse-train. This provides a means for storing power within the drive circuit that would otherwise be lost due to energy in the resonant tank dissipating. This reduces energy loss between pulse-trains and allows the stored energy to contribute in forming the next high voltage pulse-train. This saves energy and therefore makes the drive circuit more efficient.

The drive circuit may be arranged to provide (an amount, such as an adjustable amount, of) real power to the fluid to be present between the electrodes in use by providing voltage at the at least two electrodes to provide a corresponding real power due to current flowing at the at least two electrodes due to discharge occurring when the voltage is above a threshold. The threshold may be a discharge ignition threshold.

According to a seventh aspect, there is provided a system for removing carbon dioxide from a gas, the system comprising: an apparatus according to the an aspect described herein, the apparatus comprising electrodes separated to allow a gas to be present between the electrodes in use; and a conduit connected to the apparatus and arranged in use to provide gas to the apparatus such that the gas passes between the electrodes, wherein an electric field is establishable between the electrodes, the electric field being configured to cause electrical discharge between the electrodes to which the gas is exposed in use. This allows the gas to be scrubbed to reduce the amount of carbon dioxide present in the gas.

The system may further comprise an engine, wherein engine may be connected to the conduit, the conduit being arranged in use to pass gas from the engine to the apparatus.

According to an eighth aspect, there is provided a method of removing carbon dioxide from a gas, the method comprising: establishing an electric field between a first electrode to which a dielectric portion is connected and a second electrode, a sub-macroscopic structure being connected to the first electrode, second electrode or dielectric portion, the electric field causing the sub-macroscopic structure to field emit electrons and electrical discharge to occur between the dielectric and the second electrode; exposing gas to be scrubbed to the electrical discharge and electrons; and providing real power to the gas on exposure to the electrical discharge and electrons.

The method of this aspect may incorporate any feature or combination of features of the apparatus of any aspect disclosed herein. For example, the real power provided may be an amount of real power, such as an adjustable amount of real power; the real power may be provided to the fluid by applying a pulse-train of bipolar voltage pulses with a limited number of pulses in the pulse-train; and/or the real power may be provided to the fluid by applying a pulse-train of bipolar voltage pulses with between one and five pulses in the pulse-train.

In the method according to the eighth aspect, the real power may be provided by maintaining the electric field strength above a threshold.

The method may further comprise exposing the sub-macroscopic structure to a free electron to induce stimulated electron field-emission from the CNT. The free electron may be emitted from an additional electron source by field-emission or stimulated field-emission. The additional electron source may be another nanostructure.

The method may further comprise providing a voltage pulse to the sub-macroscopic structure. The pulse may have a magnitude lower than a breakdown voltage of said gas.

The sub-macroscopic structure may be arranged to generate said electron beam in an environment at an absolute pressure of no less than 80 kiloPascals (kPa).

The voltage pulse may have an absolute amplitude of from 100 volts (V) to 100 kV. The voltage pulse may have a duration of from 1 ns to 1 ms. The voltage pulse may be repeated periodically. The repetition could occur with a frequency of from 100 Hz to 500 kHz. The pulse repetition may form a pulse train with a duty cycle of less than 50%.

The method may further comprise heating the sub-macroscopic structure during the field-emission. The sub-macroscopic structure may be heated to between 20° C. and 500° C. Alternatively, the sub-macroscopic structure may be heated to between 100° C. and 400° C. such as to 150° C.

According to a ninth aspect, there is provided a method of removing CO2 from a gas with electrical discharge. In the method of removing CO2 from a gas, the electrical discharge may be barrier electrical discharge.

### BRIEF DESCRIPTION OF FIGURES

Example apparatuses and methods are described in detail herein with reference to the accompanying drawings, in which:

FIG. 1A is a flowchart of a CO2 removal method;

FIG. 1B schematically illustrates the principle of an electron irradiation and electrical discharge CO2 removal technology;

FIG. 2 schematically illustrates an example larger scale arrangement shown in vertical cross-section;

FIG. 2A shows a horizontal cross-section of an example arrangement according to FIG. 2;

FIG. 2B shows a horizontal cross-section of another example arrangement according to FIG. 2;

FIG. 2C shows a horizontal cross-section of an alternative example arrangement;

FIG. 2Ai shows a horizontal cross-section of an example containing multiple versions of the arrangement shown in FIG. 2A.

FIG. 3 schematically illustrates an example stepped potential arrangement;

FIG. 4 illustrates an example CO2 removal apparatus;

FIG. 5 shows example plots of voltage, current and power applied in an example drive circuit;

FIG. 6 shows example plots of voltage against time comparing applied gap voltage to output voltage and a corresponding plot with a magnified portion of output current against time;

FIG. 7 shows a further example plot of voltage and current over time during an example pulse-train;

FIG. 8 shows an example drive circuit used with an example CO2 removal apparatus;

FIG. 9 shows a further example drive circuit used with an example CO2 removal apparatus;

FIG. 10 shows an example method of operating an example circuit; and

FIG. 11 shows an example plots of switching sequence over time and resulting voltage over time.

### DETAILED DESCRIPTION

We have developed a method to generate a large number of high-energy electrons, atoms and free radicals to remove pollutant molecules from gases.

This is achieved using electrical discharge techniques that have been found to remove pollutant molecules, including but not limited to, particulate matter, SOx, NOx, CO2, mercury (Hg), volatile organic compounds (VOCs) and Hydrocarbons (HCs) from gases.

As a general outline, an apparatus and method suitable for electron irradiation removing CO2 from gas has been developed. A gas flow containing harmful/pollutant gas (such as CO2) is introduced into the apparatus. The apparatus is provided with a plurality of electrodes (typically pairs of cathode and anode electrodes). The electrodes are separated by a gas space and a dielectric barrier.

Where anodes and cathodes are referred to herein, reference is made to two electrodes opposing one another across an air or gas gap with no other intervening electrodes, wherein the anode is defined as the electrode at the more positive potential of the two.

In various examples the apparatus includes a high-voltage, pulsed, power supply connected to the electrode pairs, which is provided by a drive circuit. This means that when gas passes between the electrode pairs, the gas is instantaneously ionized to form high-energy electrons, atoms and free radicals. When the gas flow is introduced from a gas inlet at an end of the apparatus passes through this discharge reaction zone (i.e. between an electrode pair), a portion of the CO2 present in the gas is converted to carbon (C) and oxygen (O₂, O2). This is achievable due to the electric field established between the electrodes.

Once passed between the electrode pairs, the gas flow is discharged through an outlet provided at an opposing end of the apparatus to the gas inlet. The composition of the gas after the apparatus contains a fraction of the original CO2 and carbon.

In using electrical discharge, high voltage alternating current is applied to electrodes that are typically separated by a gas space and a dielectric barrier or insulator. Other types of electrical discharge apparatuses include, but are not limited to, pulse, corona, and electron beam discharge and radio frequency, microwave, and ultraviolet light radiation sources. Of discharge devices available, at least barrier electrical discharge and a number of the other named energy sources are not known be used for removal of CO2 from air and point sources of CO2 (such as flue or exhaust gas from engines and industrial plants) before. That these forms of discharge are useful in these applications is surprising and unexpected.

Using a dielectric barrier allows sufficient energy to be provided to convert CO2 into carbon and oxygen. The dielectric material is applied over all the surface of either or both the cathode and anode. In various examples, the dielectric portion uses quartz as the dielectric material.

To augment the number of high-energy electrons produced from barrier discharge, materials that are efficient field-emitters of electrons are used in various examples. The process of field-emission involves the application of large electric fields to the surface of a material, whereby at sufficiently high electric field the vacuum barrier is reduced to the point that electrons can escape the surface of the material by quantum tunnelling. This is possible using the apparatus according to the examples due to the electric field provided to allow for the electrical discharge.

As an example of efficient field-emitters, microneedles and CNTs have been found to be very good field-emitters of electrons when exposed to an electric field. Microneedles, CNTs and other materials can produce large numbers of electrons at relatively low applied voltages because of their very high aspect ratio (for CNTs typically of around 50 to 200 nm diameter with a length of around 1 to 2 mm, i.e. 5,000 to 40,000 aspect ratio) and their low work function (typically, for CNTs, around 4 eV).

High aspect ratios cause a large field enhancement at the tips of microneedles and CNTs with several V/μm achievable at low applied voltages. The minimum electric field strength required for field-emission from a microneedle or CNT is generally around 30 V/μm. This can be achieved by varying one or more of the lengths or the diameter of the microneedles or CNT, the distance between the electrodes used to create the electric field, and the applied voltage. If an array of microneedles or CNTs is used the density of the array can also be varied to vary the electric field strength since microneedles and CNTs tend to shield one another.

A technique, which will be referred to herein as stimulated electron field-emission, has been developed to further increase the numbers of electrons emitted by microneedles and CNTs. This technique involves stimulation of the microneedles or CNTs by energetic electron impact. This process is similar to the process of secondary electron emission in bulk materials where an energetic electron impinging on the surface causes a large quantity of bound electrons close to the surface (up to approximately 10 nm from the surface) to escape the material.

Stimulated electron field-emission is greatly enhanced in arrays of microneedles or CNTs, in part due to their large surface area and low density when compared with a bulk material such as a metal. An energetic electron travelling through a nanotube array travels a longer distance compared to an electron scattering through a bulk material due to the relatively low density of the array and the relatively large number of surfaces from which the electron can scatter. This deeper penetration leads to release of more electrons.

Electron field-emission and stimulated electron field-emission are very efficient processes in microneedles and CNTs in vacuum, but become less efficient at higher pressures. For example, exhaust gases are typically at an absolute pressure of a little above atmospheric, e.g. 105 kPa, with fluctuations e.g. within a range of approximately 87 kPa to 140 kPa. This reduction in emission efficiency is perhaps due to the reduction of electric field caused by the high density of charged particles that forms in front of the free tips of the microneedles or CNTs. A technique which can be used to maintain the instantaneous efficiency of electron production in nanotubes in high pressure environments (e.g. at around atmospheric pressure, for example 80 to 150 kPa) is to apply a series of voltage pulses to the microneedles or CNTs.

In combination with the electrical discharge, it is proposed herein to use electrons emitted from one or more microneedles or CNTs by field-emission to scrub gases such as air and flue emissions from combustion engines, e.g. in ships and other vehicles, power plants and incinerators. As such, according to some examples, one or more arrays of microneedles or CNTs are provided for this purpose. In various example the apparatus is arranged, as described below, to cause emission of electrons from microneedles or CNTs by field-emission and stimulated field-emission.

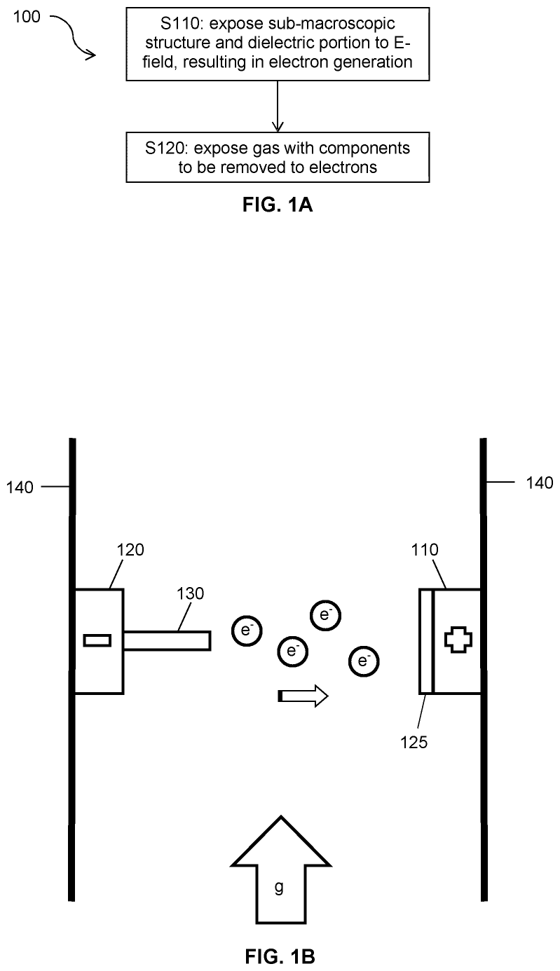

FIG. 1A is a flowchart of an example scrubbing method 100. At S110, a sub-macroscopic feature and a dielectric portion are exposed to an electric field, resulting in the field-emission of electrons from the sub-macroscopic feature and electric discharge between the dielectric and opposing electrode. At S120, gas is exposed to those electrons in order to remove components, such as CO2 from the gas.

FIG. 1B schematically illustrates the principle of this electron irradiation and electrical discharge scrubbing technology. Two electrodes, an anode 110 and a cathode 120, are located so that they facing each other. In this example, a dielectric portion 125 is located on the anode. This dielectric portion provides a coating on the entire surface of the anode.

The example in FIG. 1B also includes a sub-macroscopic feature 130 located between the anode 110 and the cathode 120. In this example, the sub-macroscopic is electrically connected to the cathode.

The sub-macroscopic feature 130 field-emits electrons (e−, e⁻) in response to the presence of an electric field between the anode 110 and cathode 120 when a potential difference is established between them. The electric field between the anode and cathode also causes electrical discharge (in the form of dielectric barrier electrical discharge) between the dielectric portion 125 and cathode 120.

The electrodes are coupled to a housing in order to locate the dielectric portion 125 and sub-macroscopic feature 130 in the vicinity of a container 140 containing gas (g) to be scrubbed such that an interior of the container can be exposed to the field-emitted electrons and electrical discharge.

Using the example in FIG. 1B, CO2 in the gas in the container 140 is able to be reduced. The major chemical reaction and energies required to allow those reactions to occur (in electron volts, eV) in the conversion of the CO2 into carbon and oxygen are as follows:

$$( 1 ) {CO}_{2} + {e}^{-} \to CO + \frac{1}{2} {O}_{2} ( 2.94 eV )$$

$$( 2 ) CO + {e}^{-} \to C + \frac{1}{2} {O}_{2} ( 11.11 eV )$$

The notation “−” indicates the relevant entity has a negative charge.

For a compact arrangement, the anode 110 and/or cathode 120 can be attached to the interior of the container such that each of the dielectric portion 125, sub-macroscopic feature 130 and a surface of the cathode extends into the gas and the electrical discharge and electrons traverse a cross-section of it. Many other arrangements could be envisaged however. For example, the dielectric portion and/or sub-macroscopic feature and surface of the cathode could be located outside of, but close to, the container with a window (aperture) in the container side permitting electron access and a surface at which the electrical discharge is able to initiate/terminate. Such an arrangement may for example be chosen to make retrofitting of the apparatus to an existing chimney of gas conduit easier, or for ease of maintenance of the dielectric portion and/or sub-macroscopic feature part of the apparatus. The cathode and housing need not be co-located.

The field-emission rate of the sub-macroscopic feature 130 can be improved by tailoring a voltage pulse frequency of the voltage applied between the anode and cathode and/or by stimulating the sub-macroscopic feature with energetic electron/ion bombardment.

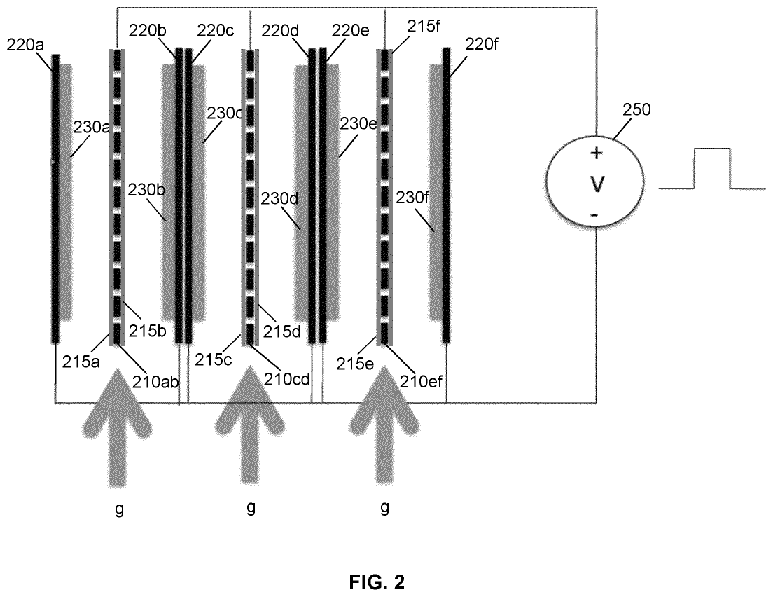

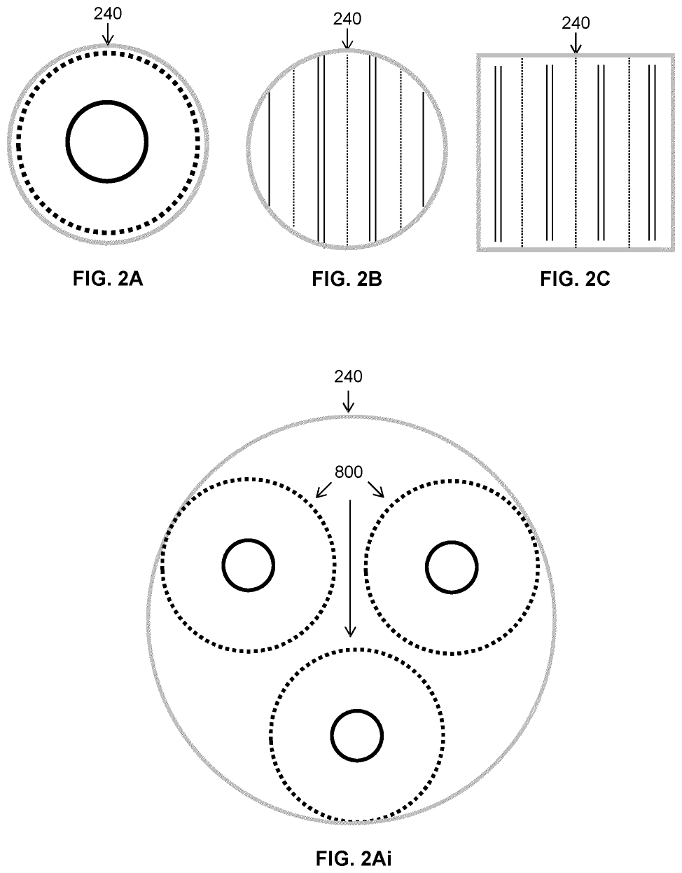

It may be more practical, such as in an industrial setting, to use arrays of sub-macroscopic features rather than individual sub-macroscopic feature. It may also be beneficial to provide multiple sets of anode-dielectric-cathode-sub-macroscopic feature apparatuses. FIG. 2 illustrates such a larger scale arrangement shown in cross-section through a gas conduit. Arrangements could also be envisaged wherein multiple sets of anode-dielectric-cathode-single sub-macroscopic features are used, or in which there is a single set of anode-dielectric-cathode-sub-macroscopic features array. FIG. 2 shows six sub-macroscopic feature arrays as an illustrative example. In other examples, other numbers of arrays are used.

In FIG. 2, arrays 230 of sub-macroscopic features are provided on conductive substrates 220, which act as cathodes opposed to anodes 210. The anodes are all electrically connected to the positive terminal of an electrical supply 250, while the cathodes are electrically connected to its negative terminal. The anodes are also coated with dielectric portions 215.

Gas (g) to be passed between the electrodes rises up between the anodes 210 and cathodes 220 and is thus exposed to electrical discharge between the dielectric portions 215 and cathodes 220 and electrons field-emitted by the sub-macroscopic feature arrays 230. The separation of each sub-macroscopic feature array from its corresponding dielectric portion could for example be approximately 0.5 to 1 cm.

The rate of electron emission from the sub-macroscopic feature arrays 230 can be increased if electrical supply 250 is a voltage controlled supply operated to send a voltage pulse to the cathodes, with the cathodes being electrically connected to the sub-macroscopic feature. Such a voltage pulse could suitably have an absolute amplitude of from 100 V to 100 kV, for example 30 kV works well for gas mixtures up to about one atmosphere absolute pressure. The pulse voltage should be below the breakdown voltage for the gas mixture (the voltage necessary to cause electric arc independent of the electrical discharge able to be established due to the dielectric portions 215). This maximum voltage can be calculated using Paschen's Law for the specific gas mixture and pressure. The pulse could have a duration of from 1 ns to 1 ms, for example 200 μs. A series of voltage pulses is employed. A periodic voltage pulse train could be used, for example with a frequency of from 100 Hz to 10 MHz, e.g. 1 kHz. Suitably, a duty cycle of less than 50% can be employed. Optimal pulse parameters depend on the geometry of the apparatus as well as gas velocity and composition.

As mentioned above, FIG. 2 shows a cross-section through a gas conduit, such as a passage through which is passed, a flue, exhaust or chimney. This can correspond to two arrangements of anodes and cathodes as shown in FIGS. 2A and 2B, which respectively show horizontal cross-sections of the two arrangements as implemented in gas conduits of circular cross-section. A similar apparatus could be used in gas conduits having cross-sections of other shapes, for example square or rectangular. Apart from where otherwise indicated with reference numerals, in FIGS. 2A and 2B dotted lines indicate anodes and solid (i.e. non-dashed or full) lines indicate cathode-array arrangements.

According to the example shown in FIG. 2A, within gas conduit 240 are concentrically arranged (from outside to inside) an anode and a central cathode.

According to the arrangement of FIG. 2B, within gas conduit 240 are arranged substantially flat plate (from left to right) cathode, anode, back-to-back cathode pair, anode, back-to-back cathode pair, anode, cathode. The plates could be of varying widths so as to extend all the way across the chimney as shown. This maximises the volume of gas passing between plates. Alternatively, the plates could all be substantially the same width for ease of manufacture.

A slightly different arrangement is shown in FIG. 2C. In this case, the container wall is conductive (such as due to being metallic) and acts as an anode. For instance, container wall could be in electrical contact with the anodes indicated by dotted lines. From left to right the electrodes are thus container wall anode, back-to-back cathode pair, anode, back-to-back cathode pair, anode, back-to-back cathode pair, anode, back-to-back cathode pair, container wall anode. The container walls, and optionally the other anodes, could all be grounded, with the cathodes held at a negative potential. A container of square cross-section is shown in this case, but the principle of using the container walls as electrodes could apply to other cross-section shapes.

Scaling the kinds of arrangements shown in FIGS. 2 to 2C up to sizes typical for exhaust chimneys, a 1 square metre (m²) cross-section gas conduit could for example have sub-macroscopic array pairs repeated across the cross-section at a pitch of approximately 2 centimetres (cm). The number of arrays needed would thus be of the order 100. In each case, each of the anodes of course have dielectric portions thereon.

The arrangements shown in FIGS. 2 and 2B all involve back-to-back cathode pairs. As shown in FIG. 2, each cathode of a pair could have a separate electrical connection to the voltage supply 250. A single electrical connection can be used to each pair if the cathodes of each pair are electrically connected to one another. Alternatively, in place of each back-to-back cathode pair a single cathode could be used with a sub-macroscopic feature array located on both sides of it.

The anodes could be metallic meshes. When the anodes are metallic meshes, the dielectric portion is coated on to the mesh so as to maintain the mesh structure. In other words, the dielectric coating is provided with apertures that align with apertures in the mesh.

If each anode is provided by a mesh, some electrons field-emitted by the leftmost array 230a as illustrated in FIG. 2 can pass through the anode 210ab and go on to cause stimulated field-emission in the next array 230b. This effect is enhanced if the potentials of the cathodes are stepped, i.e. (using the example shown in FIG. 2) the leftmost cathode 220a is at the lowest potential, the next cathode 220b is at a slightly higher potential (but still lower than the leftmost anode 210ab). Such potential stepping could be achieved using placement of appropriately rated resistors between electrodes (not shown).

Although in this example the second cathode 220b is at a higher potential than the leftmost cathode 220a, the second cathode 220b is still referred to as a cathode not an anode since the anode 210ab, at a higher potential than both cathodes 220a and 220b, separates the two cathodes. This is consistent with the above statement that where anodes and cathodes are referred to herein, reference is made to two electrodes opposing one another across an air/gas gap with no other intervening electrodes, wherein the anode is defined as the electrode at the more positive potential of the two.

As an example, the leftmost cathode 220a could be at −1.3 kV relative to the leftmost anode 210ab, which is grounded (e.g. at 0.0V), and the next cathode 220b could be at −1.0 kV. An electron coming from the leftmost cathode 220a will have 1.3 keV of energy at the anode mesh 210ab and it only needs 1 keV to reach the next cathode 220b. This stepped pattern could be repeated across the three cathode-anode-cathode cells of the arrangement.

In some examples, such as the example shown in FIG. 2, the cathode(s) and anode(s) are flat plates that face one another with a dielectric material between them (such as coated on each anode). In those examples, the plates are able to be mounted in an upright (such as vertical) position to prevent plugging with particulate matter. The rows of plates are supported by a mechanical structure and suspended by insulators from the top of the casing so that the plane of the plates is able to be parallel to the flow direction of the flue gas within a casing in which the plates are located. In this manner, a maximum amount of the flue gas is treated by the electrical discharge with a minimum pressure drop across the apparatus. In some examples, a plurality of rows of plates are mechanically fastened together, one on top of the other, to form a stack that reaches substantially from the top to the bottom of the casing.

Although flat plate cathode and anode configuration may be a preferred arrangement in some examples, different arrangements are also possible. Such arrangements include cylindrical cathode electrodes and flat plate anode electrodes, and cylindrical cathode electrodes centred in the middle of cylindrical anode electrodes. In these example arrangements, the cathode electrodes and anode electrodes may have identical construction (with, for example, one set of electrodes having one or more sub-macroscopic structures thereon and the other set of electrodes having dielectric portions thereon), and differ only in that one is wired to the power supply and the other is wired to ground. In those examples, in operation, the high voltage and ground electrodes would alternate along an entire row, and have ground electrodes at the end. This allows a high voltage gradient to exist between the electrodes.

In some examples, a coaxial tube-style reactor arrangement is used, such in the arrangement shown in FIG. 2A. In examples using a coaxial tube-style reactor arrangement one electrode is provided by a conductive tube, a centre electrode is secured inside along the central longitudinal axis of the conductive tube, and a dielectric material is disposed between them within the tube. In various examples, the tubes are arranged in tube bundles, such as shown in FIG. 2Ai.

FIG. 2Ai shows a gas conduit 240 in which a bundle of tubes 800 are arranged, each bundle having an arrangement of electrodes corresponding to the arrangement shown in FIG. 2A, namely an anode coaxially arranged around a central cathode.

When there are multiple tubes or tube bundles, the actual number of bundles stacked on top of each other and side by side are engineering decisions made dependent on the requirements of the system for which apparatus is to be used. In such examples a plurality of coaxial electrode tubes are secured in a spaced relationship to each other typically using a rectangular structure. Various examples include wire electrodes secured inside the coaxial electrodes along the central longitudinal axes of the tubes. Although the term “wire” is used, these electrodes may instead be rods, or other shaped material smaller than the inside diameter of the tubes.

Coaxial reactors have improved performance of dielectric barrier electrical discharge over flat plate electrodes. This is because it is typically easier to establish a barrier discharge within the whole discharge area in a coaxial reactor than flat plate reactor. Additionally, temperature gradients between the top and bottom of a flat plate reactor often provide inhomogeneous reactions, which decrease reactor efficiency. This is because in flat plate reactors the discharge causes the top of a plate is hotter than the bottoms and the middle is hotter than the sides. Coaxial reactors, on the other hand, tend to “light off” (i.e. generate discharge) more evenly throughout the whole tube as soon as temperature and power requirements reach the threshold for the particular reactor geometry. This makes the reaction more homogenous. The result of this is that more gas is exposed to the barrier discharge, meaning more gas is treated.

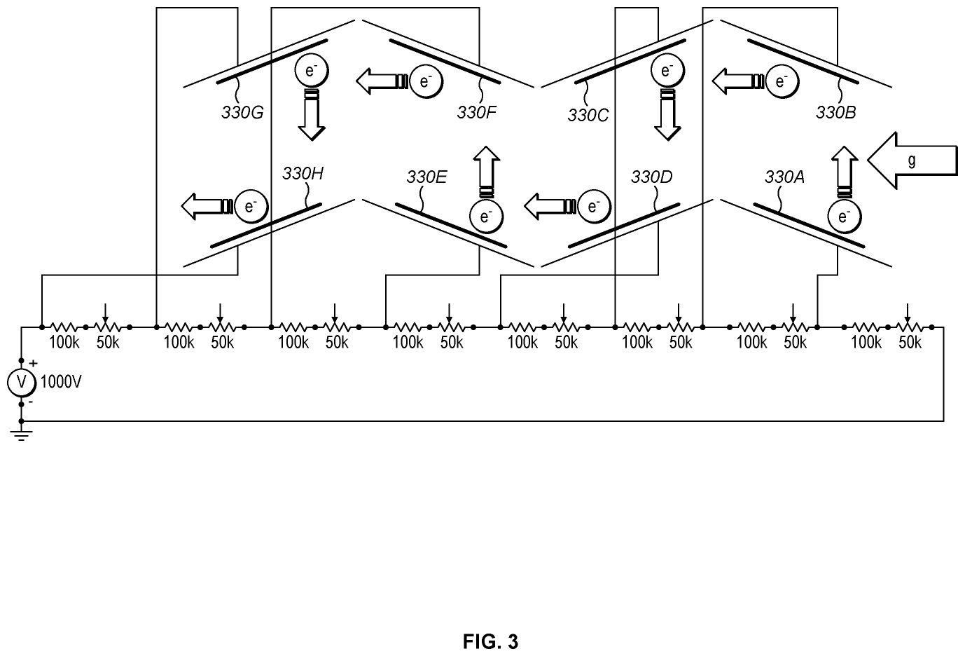

As mentioned above, FIG. 2 shows an example that uses meshed anodes. An alternative to using meshed anodes is a stepped potential arrangement such as that shown in FIG. 3 could be used. The sub-macroscopic feature arrays are arranged in a double zigzag configuration with each array being located on a substrate forming an electrode at a slightly higher potential than the last. This is achieved by the electrodes being connected in series, alternating with resistors. Array 330A field-emits electrons, some of which impinge on array 330B. Array 330B consequently emits electrons by stimulated field-emission, some of which impinge on array 330C and so on in alphabetical order all the way to array 330G as indicated by the arrows. Some of the electrons emitted by each array will likely also impinge on other arrays than just the one with the next highest potential, the path taken by each free electron will depend on the electric field it travels through, generated by a combination of all the electrodes.

In the arrangement shown in FIG. 3, there are examples where every electrode is coated with a dielectric portion. In such examples, the sub-macroscopic feature arrays may be located on the respective dielectric portions. In other examples using the arrangement of FIG. 3, every other electrode, such as the electrodes on which sub-macroscopic feature arrays 330B, 330D, 330F and 330H are located, is coated with a dielectric portion. In these examples, on the electrodes coated with a dielectric portion the CNT arrays may be located on the respective dielectric portions. The various examples that include dielectric portions allow electrical discharge to pass between the electrodes while also allowing field emission from the sub-macroscopic feature arrays.

Before passing through the apparatus, the gas may be pre-treated. For example, the gas may pass through an electrostatic precipitator to remove particulate material. The gas may also be cooled, for example using a heat exchanger or by spraying or atomising cold water or another liquid or solution through it.

Following the gas being passed through the apparatus, the gas may also undergo further treatment. For example, the gas may pass through a collection device to collect particles entrained in the gas flow, such as particles that have been converted from CO2. These particles typically include carbon, which is captured in a particle filter. The particle filter is typically a standard particle filter, such as an electrostatic precipitator (also referred to as “ESP”) or a cyclone filter. Since the other output component of the CO2 conversion process is oxygen, this is typically allowed to pass out of the apparatus without being captured or further processed.

The sub-macroscopic structures (such as microneedles, CNTs or other structures described above) can be coated, either entirely or partially, e.g. on their free ends, with a low work function coating, for example caesium or hafnium, to improve the field-emission rate.

Alternatively or additionally, the sub-macroscopic structures could be doped with an electron transport enhancing or electrical conductivity enhancing material to improve the field emission efficiency. For example, doping with nitrogen causes metallic behaviour in semiconducting CNTs.

As an issue specific to fabrication of CNTs, this typically results in the production of a mixture of single walled CNTs (SWNTs), which tend to come in a mixture of metallic and semiconducting types, and multi walled CNTs (MWNTs). Since MWNTs and metallic SWNTs are better electrical conductors than semiconducting SWNTs, a fabrication process which favours a high percentage of either or both of the former types of CNTs relative to the latter is preferable.

Field-emission in semiconducting SWNTs follows the same physical process as metallic SWNTs but electrical conduction through the nanotube is not as efficient which can lead to charging and increase in the vacuum (or surface) barrier, reducing the field-emission efficiency. It may be possible however to improve the efficiency by further exciting the system by for example using a higher applied voltage and/or shining a laser on the CNTs.

Sub-macroscopic structure arrays can become clogged with dust when left exposed. If the arrays are in direct contact with gases as illustrated they can also become clogged with any small particulates which are not successfully removed by any gas preconditioning. If ammonia is added, for example, then ammonium sulphate nitrate salt particles can also coat the array surfaces (the particles being generally too large to penetrate the arrays to clog them). Sub-macroscopic structures can also be damaged by discharges and shorts, which can occur during operation due to ionisation of the gas. Damage to the sub-macroscopic structures can also occur due to collisions with accelerated ions. For all of these reasons, the field-emission performance of sub-macroscopic structures arrays in high pressure environments (for example at around atmospheric pressure, for example 80 to 150 kPa) tends to decrease over time. All of these problems, which were not encountered for previous emission systems, which typically use CNTs in (near) vacuum, can be solved by heating the arrays, for example to around 600 to 800° C. for 1 to 3 hours in an inert gas. This anneals the sub-macroscopic structures, repairing broken bonds and recovering the original shape. Surface dust burns off and any adsorbed gases are desorbed.

In various examples the arrays are heated during use to further effect continuous annealing and to reduce the sticking coefficient to limit particulate deposits. In some examples, such heating is performed by a heating element affixed to the back of the array substrate. In alternative examples, ohmic heating of the substrate itself is employed.

An example ohmic heating arrangement would include a current controlled power supply used to heat substrates on which the sub-macroscopic structures are located. The current controlled power supply and the voltage controlled power supply could both be grounded through the substrates (cathodes).

If a low work function coating is employed, then a coating having a high melting point is preferred. For example, coatings having melting points above 400° C. would be suitable, e.g. coatings comprising hafnium, which has a melting point of 2231° C. This allows for sub-macroscopic structures, such as CNTs, to self-repair by heating as described above, and also ensures the coating remains intact even when exposed to hot exhaust gases.

In the various examples set out herein, the apparatus can be maintained at temperatures between 20° C. and 400° C., typically at about 150° C.

A system combining bare sub-macroscopic structures, and/or sub-macroscopic structures with a low work function coating, and/or sub-macroscopic structures with a catalytic coating could be used to achieve optimal performance. Example catalytic coating materials include vanadium oxide (V₂O₅), zinc oxide (ZnO), manganese oxide (MnO₂) and tungsten trioxide (WO₃). These materials can for example be coated directly on to the sub-macroscopic structures, or over a titanium dioxide (TiO₂) coating. Titanium dioxide is known to provide strong mechanical support and thermal stability to the catalysts. Other combinations of such catalysts could also be used. For example V₂O₅—WO₃/TiO₂. To implement this TiO₂ could first be evaporated onto the nanotubes and then V₂O₅ and WO₃ could be deposited.

The sub-macroscopic structures, when hollow, could be filled fully or partially with a stiffening material to make them stiffer and/or so that they bond more strongly to the substrate surface. This makes them more resistant to damage. For example, a transition metal filler such as titanium, iron or copper could be used. Suitably, the filling material can be the substrate material and/or a combination of the substrate material and carbon (e.g. a carbide of the substrate material). Sub-macroscopic structures bonded to a titanium substrate could be filled with titanium carbide to produce very well bonded sub-macroscopic structures.

As an alternative to CNTs, or additionally for the same purpose, other types of sub-macroscopic structures, such as nanostructures or microstructures, that field-emit electrons could be used, such as carbon nanohorns, silicon nanowires, titanium dioxide nanotubes or titanium dioxide nanowires. High aspect ratio nanostructures provide for more efficient field emission, for example nanostructures having an aspect ratio of at least 1,000 could be used. An advantage of using nanowires is that large arrays of vertically aligned nanowires can be easily manufactured on an industrial scale. These examples do not field-emit as efficiently as CNTs, but their field-emission could be improved by coating with low work function materials as described above. Alternatively or additionally, the field emission could be made more efficient by doping with electron transport enhancing or electrical conductivity enhancing materials. For example, Group III (acceptor) or Group V (donor) atoms (e.g. phosphorous or boron) could be used in silicon nanostructures.

If titanium dioxide is used, either to form the nanostructures or to coat them, the temperature of the nanostructures (whether as a result of exposure to hot exhaust gas or deliberate heating for self-repair as described above) should be kept below 600° C. Above this temperature titanium dioxide changes from an anatase structure to a rutile structure.

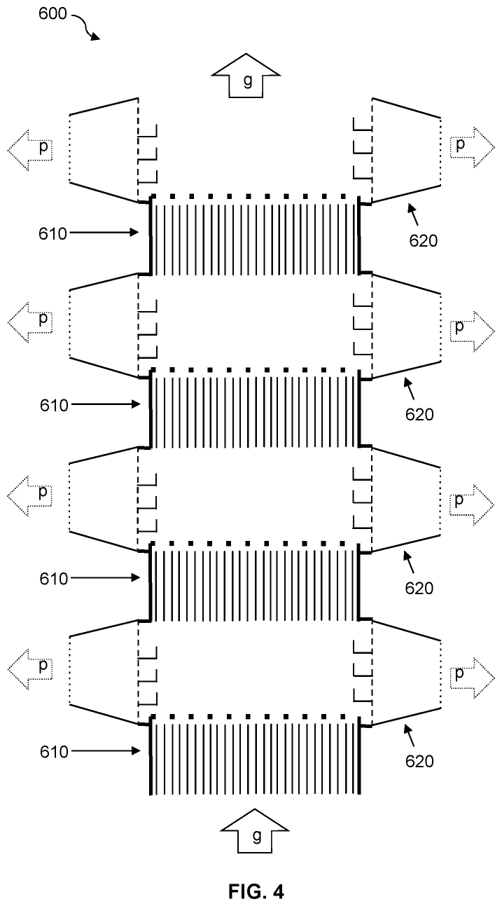

FIG. 4 schematically illustrates an example arrangement 600 of the type of apparatus described above in a gas conduit. Stacks of sub-macroscopic structure arrays 610 alternate with particle precipitator/collectors 620 along the path of the gas flow g. There could for example be four sub-macroscopic structure array stacks alternating with four particle precipitator/collectors. Particles p are directed out of the chimney towards hoppers. In examples using this arrangement, dielectric portions are coated on electrodes to allow electrical discharge to occur.

The sub-macroscopic structure arrays could for example be formed on plates 1 m wide and 0.2 m high. They could be vertically separated by e.g. 0.3 m. In the quad-module example shown in FIG. 4, the total height of the apparatus 600 would therefore be 2 m. Each sub-macroscopic structure array stack 610 could for example comprise 50 sub-macroscopic structure array pairs, for example arranged as shown in FIG. 2C with 49 back to back pairs, plus a single array at each of the left and right edges.

When using a dielectric barrier discharge (DBD) device, which a device one implementing the apparatus shown in FIG. 1B provides, we have developed a process that implements a high frequency sinusoidal waveform with varying amplitude, resembling a wavelet-type waveform. In various examples, the wavelet is generated by connecting an inductor in series with a DBD device, which provides a capacitance. This forms a series resonance circuit, also referred to as a series resonant tank, which is capable of being excited at a resonance frequency. When excited at a resonance frequency repeatedly for several cycles using bipolar voltage pulses, this allows the DBD device to be excited with a high voltage slew rate while substantially reducing current stress, and which lowers the peak power processed by the power electronics. As such, voltage gain achieved in the resonant tank provides the high ignition voltage levels for the DBD device, instead of using a pulse-transformer with a high turns ratio to provide the voltage gain. Relevant attributes of the resonant tank are therefore the achievable voltage gain and the ability to compensate for the reactive power of the DBD device.

While pulses could be provided through a number of mechanisms, we have found that applying several consecutive bipolar voltage pulses to form a pulse-train allows a higher pulse repetition frequency to be applied, and therefore the capability of power transfer is substantially increased over a system using a single pulse. As an example, by applying this process, the pulse repetition frequency is able to be increased by at least ten times over such a system. This is achievable in combination with the use of silicon carbide semiconductor technology as described in more detail below.

Repetition frequency of pulses is limited by a maximum operating temperature of power electronics. In general, pulse-power converter designs take advantage of the slow thermal response. This means that if a high pulse repetition frequency were used in a conventional pulsed system, dissipated peak power would be too large to stay within safer operating temperatures of the power electronics. This is avoided in the examples described herein by using the pulse-train modulation described below. Additionally, this is avoided by limiting the maximum number of discharge ignition events produced from a single pulse-train and then having a period that allows cooling to occur before the next pulse-train.

By implementing a pulse-train of several consecutive bipolar voltage pulses as described in relation to the examples set out herein, even if the number of discharge ignition events is limited to between one and five, this is achieved while providing energy transfer at very high efficiency, such as at about 90% efficiency or greater.

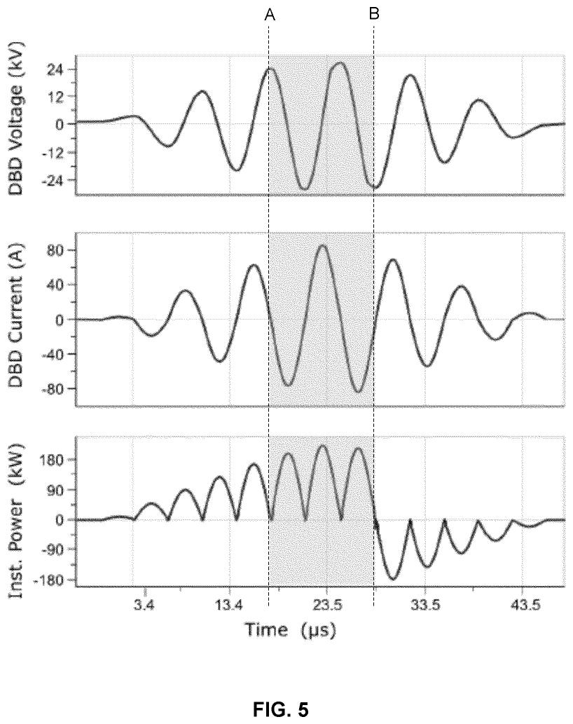

As shown in FIG. 5, the use of consecutive bipolar voltage pulses creates three modes of operation induced at the DBD device. The first mode, which occurs between 0 microseconds (μs) and time A in FIG. 5, is the charging of the resonance circuit. This builds up the potential difference across the electrodes in the DBD device. As set out above, this is achieved by applying consecutive bipolar voltage pulses at the resonant frequency of the resonant tank.

In the plots shown in FIG. 5 this can be seen to be a sinusoidal wave at consistent frequency that steadily increases in amplitude for both voltage and current. This results in an instantaneous power level of a rectified sine wave (as the multiplication of rectangular voltage and sinusoidal inductor current) with a steadily increasing amplitude. The duration of the mode in the example shown in FIG. 5 is around 2.5 voltage cycles, 2.5 current cycles and 5 power cycles (one power cycle being the transition from zero to a peak and back to zero). In this example, the current waveform leads the voltage waveform by about 90°.

The second mode takes place between time A and time B in the example plots of FIG. 5. This mode is reached when the voltage reaches the ignition or breakdown voltage (Vₜₕ) causing dielectric barrier electrical discharge between the electrodes of the DBD. This delivers power to the plasma and should last only a few discharge cycles for most efficient pollutant reduction. During this mode the voltage amplitude remains above the Vₜₕ level due to continued excitation of the resonant tank at the resonant frequency. In the plots it can be seen that the voltage and current continue in a sinusoidal wave with consistent frequency. The amplitude of the waves varies slightly over the duration of this period (increasing to approximately the half way point of the mode's duration and then begins to decrease).

The example shown in FIG. 5 is based on the DBD device having a capacitance of approximately 3.0 nanoFarads (nF). The voltage has a peak at about ±24 kilovolts (positive-negative 24 kV) and a current of ±80 Amps (A). In other examples the capacitance of approximately 1.0 nF, but could also be approximately 45.0 nF or higher.

The voltage and current amplitude pattern is the same for the instantaneous power, which continues to be the rectified sine wave. The peak instantaneous power is about 180 kilo-Watts (kW) in the example shown in FIG. 5.

The duration of the second mode is about 1.5 voltage cycles, about 1.5 current cycles and about 3 power cycles.

During the first and second mode the resonant tank is excited by having power provided to it. During the third mode the excitation is stopped and the resonant tank discharges by draining. In some examples the tank is actively discharged by recovering the energy from the tank. A passive discharge is also possible.

Due to the excitation being stopped and a discharge path being provided, in the third mode the voltage, current and power reduce to zero. In the example plots in FIG. 5, the third mode is shown from time B onwards. The voltage and current follow a sinusoidal waveform with a consistent frequency as in the first and second modes. The power continues to be a rectified sine wave. The amplitude of the voltage and current decrease towards zero over the period of about 2.5 cycles for the voltage and about 2.5 cycles for the current.

The power plot shown in FIG. 5 is consistent with an example in which the resonant tank is passively discharged. This can be seen by the instantaneous power being inverted so as to be the rectified sine wave, but with the peaks being negative values instead of positive as in the first and second mode. The amplitude of the power decreases to zero over about five cycles.

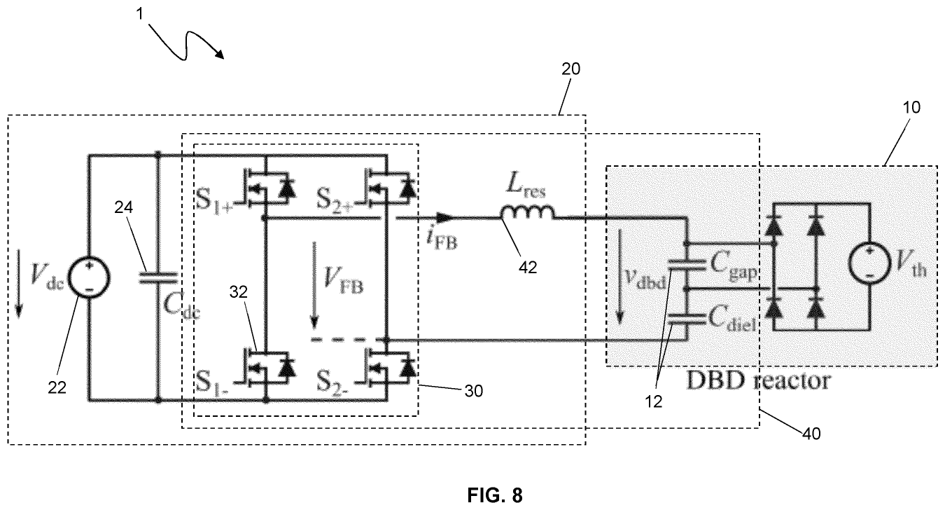

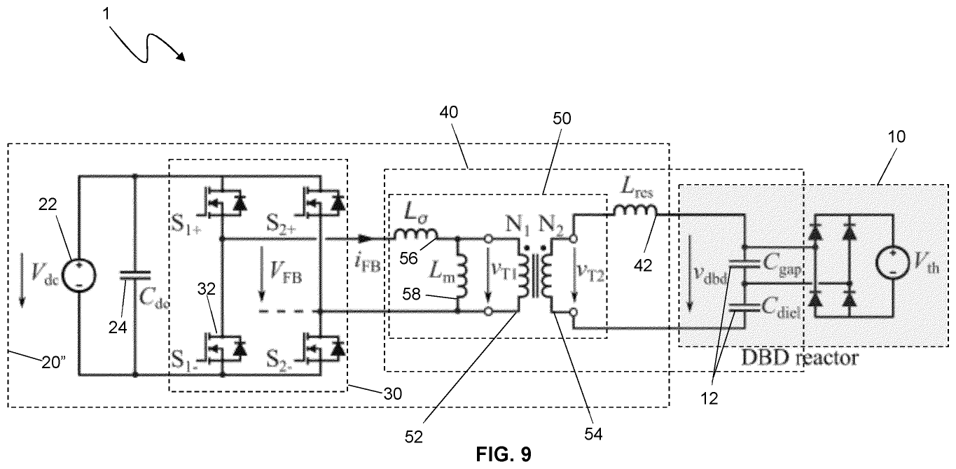

The three modes form a wavelet pulsed power process in the form of a pulse-train implemented by excitation of the resonant tank. The duration of the power transfer achieved using this process is determined by the length of time over which this excitation pulse-train is provided to the resonant tank. This is just one parameter of the excitation pulse-train that is determined by circuit by which the pulse-train is implemented. FIGS. 8 and 9 show example circuits capable of being used to implement one or more pulse-trains.

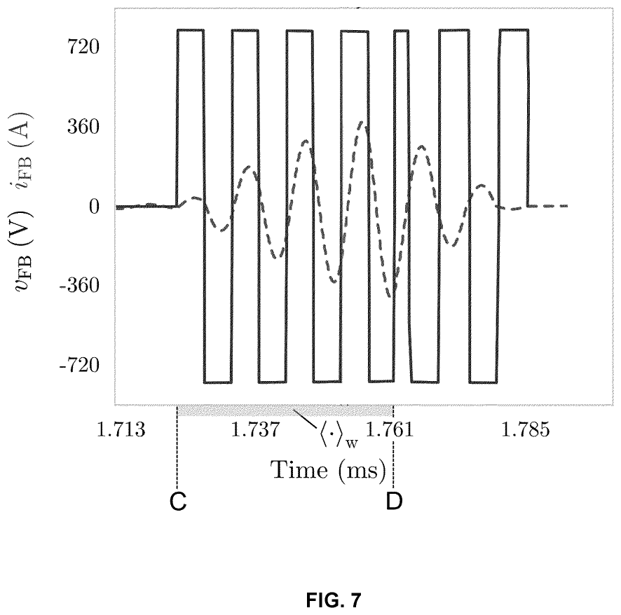

An example of the excitation applied to the resonant tank is shown in FIG. 7 below. As can be seen in FIG. 7, in various examples, the excitation takes the form of a square wave voltage waveform, the waveform comprising multiple consecutive individual pulses that together form a pulse-train. This induces a sinusoidal current in a resonant tank (the current waveform shown in FIG. 7), and provides the waveforms at the DBD device shown in FIG. 5.

While FIG. 7 does not show the dielectric barrier electrical discharge threshold, or specific include markings separating the first, second and third modes, it is possible to see in this figure where the third mode begins. At time D in FIG. 7, it can be seen that the voltage waveform has a peak at a maximum positive value that has a shorter duration than the other peaks in the waveform. This occurs due to the transition from the second mode to the third mode. At this point, the excitation is stopped, meaning voltage is no longer actively provided to the resonant tank and DBD device.

Depending on the action taken at that stage, such as whether active or passive energy recovery is used, this causes a phase shift in the voltage waveform. Passive energy recovery is used in the simulation used to produce FIG. 7, and as such, the change in the applied waveform is caused by means of freewheeling of current in H-bridge diodes. An alternate active energy recovery means applied in some examples is 180 degree phase shift causing power to be drained instead of being provided. These processes are described in more detail below along with an example inverter providing the H-bridge.

In various examples, the transition to the third mode in examples according to an aspect disclosed herein is applied after a maximum number of discharge ignition events. A number of examples limit the maximum number of discharge ignition events to only a single discharge ignition event, or to up to about five discharge ignition events. When only a single discharge ignition event is used as the maximum number, or after the last discharge ignition event at a larger maximum number, the third mode is transitioned to directly after (such as immediately after) the maximum number of discharge ignition events have occurred.

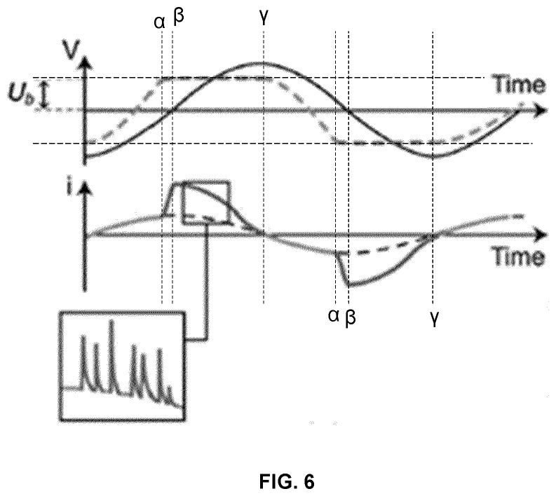

In terms of how an example excitation applied to the device translates into discharge, this is demonstrated by the plots shown in FIG. 6. This shows an upper plot and a lower plot. The upper plot is a plot of voltage against time and the lower plot is a plot of current against time.

The upper plot of FIG. 6 shows a solid line and a dashed line. The solid line is in the form of a sinusoidal wave that is at a minimum at time zero. In this example, this line corresponds to a voltage applied across a DBD device. The dashed line is in the form of a sinusoidal wave with its maximum and minimum peaks truncated to a plateau. As with the applied voltage curve, this is at a minimum at time zero, and, in this example, corresponds to a voltage across the discharge gap.

The amplitude of the gap voltage is less than the applied voltage amplitude. As the applied voltage transitions towards positive, the gap voltage increases. After about an eighth of a cycle of the applied voltage, the gap voltage turns positive. Just before the end of a second eighth of said cycle, the amplitude of the gap voltage reaches a threshold. In FIG. 6 this occurs at time α. This plateau is maintained until the applied voltage reaches a maximum, at time γ, in FIG. 6. At time γ, the process repeats itself, but with the polarities reversed, and continues to switch between movements in the positive and negative directions as long as the applied voltage continues.

As a comparison to the first, second and third modes set out above, the rise in the gap voltage corresponds, for example, to the rise in voltage during the second mode after the first fall in voltage during the second mode. From this it can be understood that discharge is able to occur during this period, and as such, the plateau in the gap voltage curve is due to the threshold voltage being reached.

The current plot of FIG. 6 shows the current at the gap induced by gap voltage. At time zero this has an amplitude of approximately zero. This increases in the form of a sinusoidal wave. Should the gap voltage not reach the threshold voltage (such as if the plots of FIG. 6 represented voltage and current during the first or third modes), then, as shown by the dashed line in the current plot in FIG. 6, the sinusoidal wave would proceed uninterrupted. However, at time α, due to the threshold voltage having been reached, ignition occurs. This causes ionisation of the medium in the discharge gap and electrical discharge to begin.

From time α, the gap current rapidly increases to a peak at time β, which corresponds to the zero-cross point of the applied voltage. Since time α is almost at the end of a quarter cycle of the applied voltage cycle, this is a very short period relative to the cycle of the current curve. From time β, the current then, in a sinusoidal manner, decreases to zero at time γ, at which point it returns to its original form and amplitude range. This cycle continues in parallel with the gap voltage and applied voltage.

As can be seen from this, the amplitude of the current is simply increased to an amplified level.

The main current plot of FIG. 6 shows a continuous curve between time α and time γ. As noted above this is the time during which discharge occurs. This period is therefore able to be considered to be a macro-discharge period, and time α is when a discharge ignition event occurs. As is shown by the magnified section of the current plot of FIG. 6, the current curve does not have a continuous form however. Instead, the curve is made up of many current spikes that are so close together that they cause the curve to appear continuous. Each spike represents a micro-discharge or transient filament, which is initiated from a single point on one of the electrodes (such as from a sub-macroscopic feature 130 on the electrode 120 shown in FIG. 2). It is the connection each of these filaments provide between the opposing electrodes (one electrode 110 of course having the dielectric layer 125 thereon as shown in FIG. 2) that causes the current spike because the filament provides a current path across the discharge gap. Due to these micro-discharges ionising the medium in the gap and passing high energy electrons into the medium, enough energy is present to drive chemical reactions that, for example, breakdown pollutants in the medium.

Turning to example drive circuits that are capable producing a pulse-train, generally illustrated at 1 in each of FIG. 8 and FIG. 9 is a circuit diagram of an example system suitable for providing dielectric barrier discharge. This system includes a DBD device 10, also referred to as a DBD reactor, and corresponding to the apparatus shown in FIG. 1B.

The DBD reactor 10 is represented in each of FIGS. 8 and 9 by a model. The model is a diode bridge with a power input (also referred to as a power source) providing a voltage of Vₜₕ in use. The electrodes of the DBD device are shown in the model as being connected across the diode bridge.

The electrodes (specifically the gap between the electrodes, which may be referred to as a “dielectric discharge gap”) and the dielectric barrier mounted to one of the electrodes are represented in FIGS. 8 and 9 by capacitors 12. This is because the electrical functionality the gap and dielectric barrier provide to the system when represented as a circuit is capacitance.

The capacitance provided by the dielectric discharge gap is shown as being connected directly across the diode bridge. The capacitance provided by the dielectric barrier itself is shown as being connected at one end to the diode bridge in parallel with the capacitance provided by the gap. The other end of the capacitance provided by the dielectric barrier is not connected to the diode bridge. This is instead connected to a drive circuit arranged to drive dielectric barrier electrical discharge across the gap between the electrodes.

While represented by a model in FIGS. 8 and 9, the DBD device 10 capacitance is determined predominantly by the capacitance of the medium (typically gas, such as air) in the dielectric discharge gap. This is typically due to the dielectric constant of the medium being about 1 and the dielectric material being significantly higher than 1, such as between about 3 and 6 (when measured at about 20 degrees Celsius at about 1 kHz). As the medium and dielectric are connected in series, it is the smaller capacitance that is dominant, and therefore, due to these relative dielectric constants, the effective capacitance of the DBD device is governed by the medium

Further, the contribution from the capacitance of the medium in the gap, this is approximately constant and does not depend on temperature of composition of the medium in the gap. This “air-gap” capacitance is therefore approximately constant because, as explained in more detail below, the pulse-trains used in examples according to an aspect disclosed herein limit the number of discharge ignition events to the extent that minimal change occurs to this capacitance. The same cannot be said however for known resonant systems. This is either due to the extended nature of the discharge causing a shift in the capacitance of the medium, or the medium is of a different nature, such as when surface dielectric barrier discharge devices are used.

The drive circuit is illustrated respectively at 20 and 20″ in FIGS. 8 and 9. The drive circuit has a power source 22 connected to an inverter 30. The power source is provided by a DC power supply in the examples of these figures. This is a DC link voltage supply, V_{dc}, in the examples shown.

In the example shown in FIG. 8, the inverter 30 has a circuit loop connected across it. This circuit loop has a connection to the electrodes of the DBD device 10 connecting in series across the capacitance provided by the dielectric discharge gap and dielectric barrier. This closes the circuit loop connected across the inverter.

The example shown in FIG. 9 the inverter 30 has a transformer 50 connected across it. In this arrangement it is the primary side 52 of a transformer that is connected across the inverter. The secondary side 54 of the transformer has a connection to the electrodes of the DBD device 10 connecting in series across the capacitance provided by the dielectric discharge gap and dielectric barrier.

The connection across the capacitance of the DBD device 10, and the ability to connect across this capacitance in the examples of each of FIGS. 8 and 9 causes the drive circuit 20 to be a separate, and in some examples separable, circuit from the DBD device.

In the example shown in FIG. 8, when the drive circuit 20 is connected as set out above to the DBD device 10, a resonant tank 40 is formed between the inverter 30 and the capacitors 12 provided by the dielectric discharge gap and the dielectric barrier. The inductance of the resonant tank is provided in this example by an inductor 42 connected in series with the capacitance. Some inductance will also be provided by the wiring of the resonant tank. The inverter provides the power source for the resonant tank.

In the example shown in FIG. 9, when the drive circuit 20″ is connected, as set out above, to the DBD device 10, a resonant tank 40 is formed between the transformer 50 and the capacitance 12 provided by the dielectric discharge gap and the dielectric barrier. The inductance of the resonant tank is provided by an inductor 42 connected in series with the secondary side 54 of the transformer and the capacitance in combination with stray/leakage inductance of the transformer represented in FIG. 9 by inductor L_{σ} at reference numeral 56. This is shown in FIG. 9 as being connected in series with the transformer between the output from the inverter 30 and the input to the primary side 52 of the transformer.

The transformer 50 shown in the example of FIG. 9 also has magnetisation induction represented in the figure by inductor Lₘ at reference numeral 58, connected in parallel with the primary side 52 of the transformer.

In addition to providing a step change in voltage and current based on the turns ratio in the transformer 50, the transformer also provides galvanic isolation. This suppresses electromagnetic interference across the transformer from the inverter 30 to the resonant tank. A conventional magnetic core transformer is able to be used in various examples. In other examples, an Air-Core Transformer (ACT) is able to be used. Compared to a regular (i.e. magnetic core) transformer, an ACT can have a very low coupling (such as 40% instead of 98% as would typically in a magnetic core transformer) between the windings. This results in higher leakage inductance than in a regular transformer. However, this is desirable in some examples, since it allows several desirable functions for the drive circuit as a whole to be incorporated in a single component, namely galvanic isolation for safety and EMI suppression (since the transformer provides a noise barrier), voltage step-up and resonance inductance (as is discussed in more detail below). These functions are also able to be provided by a regular transformer but to a lesser extend in some examples.

Turning to the inverter 30 in more detail, in the examples shown in FIGS. 8 and 9, the inverter is provided by an H-bridge. The H-bridge has four switches 32 providing two high-side switches, S₁₊ and S₂₊, and two low-side switches, S₁₋ and S₂₋. In the example shown in FIG. 5, the inverter is provided by a half bridge. This has two switches 32 and two capacitors 34, with the switches providing one high-side, S₁₊, and one low-side, S₁₋, switch.

The switches 32 of the inverter 30 are, in the examples shown in FIGS. 8 and 9 provided by transistors. These are silicon carbide MOSFETs in the examples shown in these figures. In other examples, each switch is able to be provided by a MOSFET, such as an n-type MOSFET, silicon MOSFET; or other types of electronic switches, such as Insulated Gate Bipolar Transistors (IGBTs), such as a silicon IGBT, Junction Field Effect Transistors (IFETs), Bipolar Junction Transistors (BJTs), or High Electron-Mobility Transistors (HEMTs), such as gallium nitride (GaN) HEMTs.

In the examples shown in FIGS. 8 and 9 a capacitor 24 is connected in parallel with the inverter 30 and voltage supply 22. This provides a DC link capacitance for the drive circuit 20. In other example, this capacitance is provided by the capacitors of a half-bridge inverter.

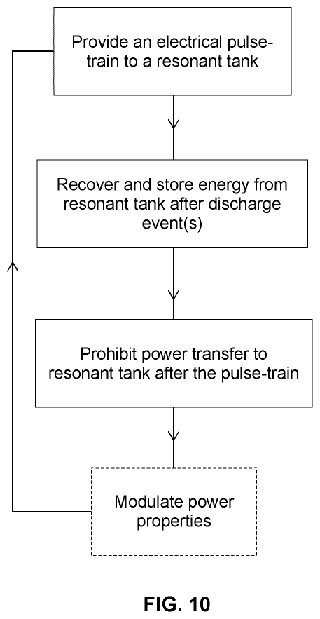

As shown in FIG. 10, the system is used to provide an electrical pulse-train to the resonant tank and to prohibit power transfer to the resonant tank after the pulse-train. There are also steps of modulating power properties in order to modify the pulse-train before a further pulse-train is provided and to recover energy from the resonant tank after the discharge ignition event(s) and store the energy. While there are examples where energy recovery is not included in this process, typically energy recovery is included in this process. The step of modulating power properties is optional however. The details of the process are set out in more detail below along with further details of power modulation and energy recovery processes.

During use of the system 1, the power supplied to the DBD device 10 needs to reach at least the dielectric barrier electrical discharge voltage level (Vₜₕ). This is needed in order to stimulate dielectric barrier electrical discharge across the discharge gap. The model circuit shown in FIGS. 8 and 9 for the DBD device shows the ability of the device to accept power and voltage clamping across the gap when Vₜₕ is reached. The power absorbed by the DBD voltage source shown in these figures is given by the product of Vₜₕ and the current impressed in the resonant tank (when the diodes are conducting). As such, when the voltage across the gap exceeds Vₜₕ, the corresponding pair of diodes in the model circuit of the DBD device are conducting, and power is being transferred to the (model) Vₜₕ voltage source depicted in the figures, representing a power transfer to the plasma. In this model, the voltage across the gap is clamped to Vₜₕ whenever dielectric barrier electrical discharge occurs.

The power to provide the dielectric barrier electrical discharge voltage is provided by the drive circuit 20 as a pulse-train. The power provided by the pulse-train is drawn from the DC link voltage source 22 at a level of about 800 V. This is fed to the inverter 30. In other examples, the voltage provided by the DC link voltage source is up to 900 V when using a silicon carbide MOSFET, and can be higher, such as 1.2 kV to 1.3 kV when using a 1.7 kV rated silicon carbide transistor.

To initiate the pulse-train, when using the system in the example shown in FIG. 4, as power is drawn from the DC link voltage source 22, the H-bridge is then used to excite the resonant tank 40. In this example this is achieved by the H-bridge outputting a 100% duty-cycle square wave voltage over the duration of the first two modes of the pulse-train (as set out above in relation to FIG. 5).

The switches 32 of the H-bridge are arranged to provide output at a switching frequency tuned to excite the resonant tank 40 at the resonance frequency of the tank. This causes only real power to be processed by the H-bridge. In order to minimize switching losses, operation slightly above the resonance frequency is feasible to achieve ZVS of the switches.

As set out above in relation to FIG. 5, the excitation of the resonant tank 40 causes dielectric barrier electrical discharge once the voltage level in the resonant tank 40 reaches Vₜₕ. This transfers power into the plasma between the electrodes in the DBD device 10.

When the second mode of the pulse-train is to be ended, the switches 32 are turned off. When using transistors as in the examples shown in FIGS. 8 and 9, this is achieved either by turning the transistors off apart from the transistor body diodes (or external anti-parallel diodes), which are left active, or the bridge voltage (v_{FB}) across the inverter 30 is phase-shifted by 180° in order to respectively passively or actively recover the remaining energy stored in the resonant tank 40.

The recovered energy is transferred to the DC link capacitor 24. This is achieved by the reversal of the power flow through the passive or active recovery described in the previous paragraph. This allows this energy to contribute to the energy used for the next pulse-train.

Passive power recovery is achieved by the transistors in the inverter 30 simply being switched off at the end of the second mode (i.e. when dielectric barrier electrical discharge is to be ended), as referred to above. Due to the arrangement of the circuit in an H-bridge or half bridge, this removes all circuit paths through the transistors and leaves a path through the transistor body diodes (which, as shown in FIGS. 8 and 9 provide a connection across the transistors). The connection of the resonant tank across the inverter as shown in FIGS. 8 and 9 relative to the diodes allows energy to flow through the diodes and into the DC link capacitor 24, 34 when the transistors are switched off.

Active power recover is instead achieved by making use of the transistors to provide a 180° phase shift in the output of the inverter 30 from the phase of the output in the second mode. Instead of allowing energy to flow into the DC link capacitor 24, 34, as occurs during passive power recovery, this drives the energy into the DC link capacitor.

The quality factor (Q) of the resonant tank equates to the voltage gain of voltage across the dielectric discharge gap (v_{dbd}) to the bridge voltage (i.e. Q=v_{dbd}/v_{FB}) at the resonance frequency (without transformer or unity turns-ratio, which would make the quality factor as Q=v_{dbd}/(v_{FB}/n), where n is the turns ratio of the transformer; the total gain when using a transformer would also be determined from the transformer step-up plus the resonance gain). The effective voltage gain of the resonant tank is determined by the power losses imposed by the equivalent series resistances (ESR) of the magnetic components and the wires connecting the electrodes of the DBD device which provide damping to the circuit. Unlike known systems that use resonant converters, in examples according to an aspect disclosed herein the effective voltage gain is not determined by the actual power being delivered to the plasma since there is no discharge occurring during charging of the resonant tank. For this reason, practical values of Q of greater than 40 allow dielectric barrier electrical discharge voltages above 30 kV from the 800 V DC link input voltage without the explicit need of a step-up transformer.

It can therefore be appreciated that once power is being absorbed by the onset of discharge ignition events in the DBD device, a lower voltage gain may cause a self-quenching effect due to the damping this causes and the Q value shift. However, since only a few discharge ignition events are wanted from each pulse-train (such as between one and about five discharge ignition events) and because there is enough momentum in the resonant tank (stored energy much larger than energy absorbed by electric discharges), this does not impose any practical challenges for the examples according to an aspect disclosed herein. On the other hand, known resonant converters are configures for comparably low voltage gains resulting from continuous power absorption by the plasma and therefore need, and are designed with, high step-up transformer turns-ratios.

The voltage across the dielectric discharge gap is determined by the capacitance of the dielectric discharge gap. This is made up of the capacitance of the dielectric and the capacitance of the gap itself. In the examples in FIGS. 8 and 9, the capacitance of the dielectric (C_{diel}) is typically much larger than the capacitance of the gap (CO_{gap}). For example, C_{diel} is typically at least ten times larger than C_{gap}. This also gives a voltage ratio of voltage across the gap (V_{gap}) compared to the voltage across the dielectric (V_{diel}) of at least 10.

When using the drive circuit 20″ of the example shown in FIG. 9, the same process as is able to be applied for the drive circuit 20 of the example shown in FIG. 8 can be used.

The power being provided by the DC link power supply is the power provided to the drive circuit averaged over the pulse-train repetition interval. The energy exchanged between the DC-link capacitor and the resonant tank during resonant tank charging, power transfer during dielectric barrier electrical discharge, and resonant tank discharging typically causes a voltage ripple across the DC link capacitors. The interval where power is transferred to the plasma by dielectric barrier electrical discharge also contributes to the DC-link voltage ripple.

In the example shown in FIG. 9, the transformer 50 provides a step up ratio of between about 1:1 and 1:10. This lower step up ratio that those of conventional pulsed-power circuits (example step-up ratios of which are set out above), allows the current passing through the primary side 52 of the transformer to be limited. When a ratio of 1:1 is used, this only provides galvanic isolation instead of providing galvanic isolation and step up in voltage when a higher step-up ratio, such as a step up ration of 1:10, is used.

The inductor 42 used in the drive circuit 20″ of FIG. 9 can be located on either the primary side or secondary side of the transformer 50. However, by locating the inductor on the secondary side (and therefore high voltage side), as mentioned above, the kVA rating of the transformer is able to be reduced. The reactive power of the DBD device 10 can then be directly compensated. Under such a reactive load matching condition, only the real power is processed by the transformer.

The galvanic isolation imposed by the transformer 50 reduces ground currents, which are currents flowing in the parasitic capacitance between electrodes of the DBD device 10 and any surrounding metallic housing. This assists in meeting electromagnetic compatibility (EMC) limits.

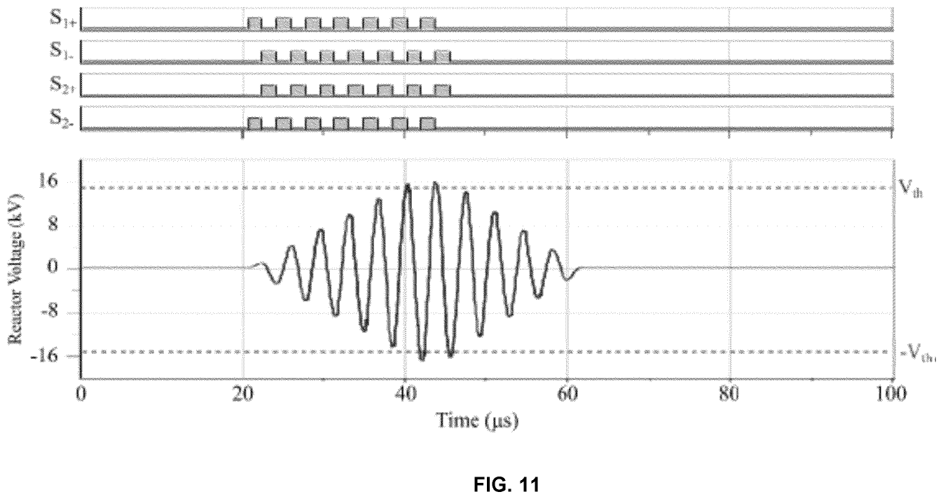

The duration of each wavelet pulse-train determines the number of dielectric barrier electrical discharge ignition events. As can be seen from FIG. 11, for a given V_{dc}, the number of excitation periods nₚ (i.e. frequency cycles) defines the effective duration of the wavelet pulse-train and the number of dielectric barrier electrical discharge ignition events once Vₜₕ has been reached in the resonant tank. This therefore determines the amount of energy transferred to the plasma per pulse-train.

The real power is adjusted by moving the bridge-leg switching frequency away from the resonance frequency. This can be achieved by increasing the switching frequency above the resonance frequency or lowering the switching frequency below the resonance frequency. This causes a phase-shift between the v_{FB} and the bridge current i_{FB}, and thus lowers the real power being transferred to the DBD reactor.

By taking this approach the high voltage gain is lowered and processing of reactive power increases. In order to maintain the high voltage gain and minimise the processing of reactive power, instead, in accordance with aspects of the present disclosure, the inverter 30 is able to be arranged in use to provide excitation close to the resonance frequency. This is achieved by keeping the phase shift between v_{FB} and i_{FB} close to zero. The average power is adjusted by varying the repetition frequency of the wavelet pulse-trains (i.e. how frequently a wavelet pulse-train is used to excite the resonant tank to cause dielectric barrier electrical discharge). This allows very high partial load efficiency to be achieved since the resonant tank is always operated at its resonance and therefore there is little to no processing of reactive power.

As mentioned above, the length of a pulse-train is variable. A pulse-train of a single duration can be seen in FIG. 11. The pulse-train illustrated in FIG. 11 is a short pulse-train, such as one that is able to be used with an example according to an aspect disclosed herein due to it producing between two and four discharge ignition events, but can be lengthened by adding further switching as described below.

In FIG. 11, each pulse-train is generated by an example drive circuit such as those shown in FIG. 8 or FIG. 9. Of the two plots shown in FIG. 11, one plot shows the state of the switches 32 within the H-bridge inverter 30. These are either in an off state (a “0” state) or an on state (a “1” state). By operating these switches in pairs, the wave pattern shown in the lower plot of FIG. 11 is producible at the DBD device.

The switch pairs are the S₁₊ switch paired with the S₂₋ switch, and the S₁₋ switch paired with the S₂₊ switch. During the first two modes of a pulse-train, the switches of each pair (i.e. the two switches within the respective pairs) are operated in phase, causing each switch to be in the same state as the other switch of the pair. In the first two modes of a pulse-train, the pairs are operated out of phase, meaning that when the switches of one pair are in one state, the switches of the other pair are in the other state.

As is conventional with an inverter, there is a “dead-time” or “interlocking time” between the switches S₁₊ and S₁₋ being switched from one state to the opposing state. This dead-time is a period of time where both the switches are turned off. This period is typically several hundred nanoseconds. This period is provided as a safety interval to avoid the DC-link power supply being accidentally shorted, since this would cause a catastrophic failure within the system.

By having the switch pair S₁₊ and S₂₋ in the on state and the switch pair S₁₋ and S₂₊ in the off state, this causes a positive voltage increase. By reversing the states, so having the switch pair S₁₊ and S₂₋ in the off state and the switch pair S₁₋ and S₂₊ in the on state, this causes a negative voltage increase. By alternating this arrangement, a sinusoidal waveform as shown in the lower plot of FIG. 11 is produced with the frequency of the waveform being determined by the length of time each switch pair is in an on and off state.

In FIG. 11 each switch pair is operated for seven on-off cycles, with the S₁₊ and S₂₋ pair being the first pair to be in the on state. This generates a pulse-train with a duration of around 40 μs and a voltage of at least Vₜₕ for about 1.75 cycles. When the switch pair on-off cycles are stopped, the third mode of the pulse-train occurs until the voltage returns to 0 V. This transfers a smaller amount of energy to the plasma than a longer pulse-train. As can be expected, this is due to a longer pulse-train having a longer period with a voltage amplitude of at least Vₜₕ than the pulse-train.

By operating the drive circuit 1 in the manner described above, during a discharge period (i.e. during a period in which a pulse-train causes the voltage to in the DBD device to be peak above the discharge threshold), the real power in the DBD device is provided when the voltage is above a threshold. This threshold allows the voltage to have a peak above the discharge threshold and therefore for discharge to occur. The period may vary in length depending on discharge requirements for causing contents of gas passing through the DBD device to be converted.

Where this application has listed the steps of a method or procedure in a specific order, it could be possible, or even expedient in certain circumstances, to change the order in which some steps are performed, and it is intended that the particular steps of the method or procedure claims set forth herein not be construed as being order-specific unless such order specificity is expressly stated in the claim. That is, the operations/steps may be performed in any order, unless otherwise specified, and embodiments may include additional or fewer operations/steps than those disclosed herein. It is further contemplated that executing or performing a particular operation/step before, contemporaneously with, or after another operation is in accordance with the described embodiments.

1. A dielectric barrier electrical discharge apparatus, comprising:
at least two electrodes arranged in use to provide at least one anode and at least one cathode, the at least two electrodes being separated to allow a fluid to be present between the electrodes in use, and at least one of the electrodes has a dielectric portion connected to at least part of said electrode;
a sub-macroscopic structure connected to at least one of the at least two electrodes and/or to the dielectric portion; and
a drive circuit connected to each of the at least two electrodes and arranged in use to establish an electric field between the electrodes, wherein in response to the presence of the electric field between the electrodes, the sub-macroscopic structure is arranged to field-emit electrons and electrical discharge is establishable between the dielectric portion and one of the at least two electrodes, and the drive circuit is further arranged to provide real power to the fluid in use.

2. The apparatus according to claim 1, wherein the drive circuit is arranged in use to provide real power to the fluid by applying a pulse-train of bipolar voltage pulses with a limited number of pulses in the pulse-train.

3. (canceled)

4. The apparatus according to claim 1, wherein the drive circuit comprises a power supply connected in use across the at least two electrodes, and an inductance connected between the power supply and at least one of the at least two electrodes thereby establishing a resonant tank in use, power being provided in use to the tank in pulse-trains and only during a pulse-train, a pulse frequency of each pulse-train being tuneable in use to a resonant frequency of the tank, power provided by each pulse-train charging and maintaining the tank to a threshold at which discharge ignition occurs, discharge ignition events per pulse-train being limited to a maximum number based on the drive circuit being arranged in use to prohibit each pulse-train transferring power to the resonant tank after the maximum number has occurred.

5. The apparatus according to claim 4, wherein the maximum number of discharge ignition events is between 1 and 5 events.

6. The apparatus according to claim 4, wherein the drive circuit further comprises a transformer, secondary windings of which form part of the resonant tank, the transformer being a step-up transformer.

7. The apparatus according to claim 6, wherein the drive circuit is arranged in use to short the primary transformer winding after each pulse.

8. The apparatus according to claim 6, wherein at least a part of the inductance is provided by the transformer.

9. The apparatus according to claim 6, wherein at least a part of the inductance is provided by an inductor.

10. The apparatus according to claim 2, wherein the drive circuit further comprises a power storage device connected across the power supply arranged in use to accept and store power discharge from the tank after each pulse.

11. The apparatus according to claim 1, wherein the sub-macroscopic structure is electrically connected to at least one of the electrodes.

12. (canceled)

13. An apparatus for removing carbon dioxide from a gas, the apparatus comprising:
a first electrode and a second electrode, the first and second electrodes being arranged in use to provide an anode and a cathode;
a dielectric portion connected to the first electrode and a sub-macroscopic structure connected to the first or second electrode or to the dielectric portion, wherein, in response to the presence of an electric field between the electrodes, the structure is arranged to field-emit electrons and electrical discharge is establishable between the dielectric and the second electrode;
a drive circuit connected to the first electrode and the second electrode and arranged in use to establish an electric field between the first and second electrodes, wherein in response to the presence of the electric field between the electrodes, the sub-macroscopic structure is arranged to field-emit electrons and electrical discharge is establishable between the dielectric portion and one of the at least two electrodes, and the drive circuit is further arranged to provide real power to a fluid to be present between the electrodes in use; and
a housing coupled to the electrodes, the electrodes being located on the housing so that the structure and the dielectric portion each extend into a container containing gas to be scrubbed such that an interior of said container can be exposed to said electrons and electrical discharge.

14.-15. (canceled)

16. The apparatus according to claim 13, wherein the first electrode is arranged in use to provide the anode.

17. The apparatus according to claim 13, wherein the second electrode is arranged in use to provide the cathode.

18. The apparatus according to claim 13, wherein the sub-macroscopic structure is electrically connected to one of the electrodes.

19. The apparatus according to claim 18, wherein the sub-macroscopic structure is electrically connected to the second electrode.

20. The apparatus according to claim 1, wherein the dielectric portion is a coating on at least part of a surface of each electrode to which the dielectric portion is connected.

21. The apparatus according to claim 1, wherein the dielectric portion is one or more of mica, fused silica, quartz, alumina, titania, barium titanate, fused silica, titania silicate, silicon nitride, hafnium oxide or a ceramic.

22.-24. (canceled)

25. The apparatus according to claim 1, wherein the drive circuit is arranged in use to provide a voltage pulse to said at least one electrode.

26. (canceled)

27. The apparatus according to claim 1, wherein the drive circuit is arranged to provide real power to the fluid to be present between the electrodes in use by being arranged in use to provide voltage at the at least two electrodes to provide a corresponding real power due to current flowing at the at least two electrodes due to discharge occurring when the voltage is above a threshold.

28.-29. (canceled)

30. A method of removing carbon dioxide from a gas, the method comprising:
establishing an electric field between a first electrode to which a dielectric portion is connected and a second electrode, a sub-macroscopic structure being connected to the first electrode, second electrode or dielectric portion, the electric field causing the sub-macroscopic structure to field emit electrons and electrical discharge to occur between the dielectric and the second electrode;
exposing gas to be scrubbed to the electrical discharge and electrons; and
providing real power to the gas on exposure to the electrical discharge and electrons.

31.-32. (canceled)

33. The method according to claim 30, wherein the real power is provided by maintaining the electric field strength above a threshold.

34.-48. (canceled)
